(19) United States
(12) Patent Application Publication
(10) Pub. No.: US 2006/0284744 A1
(43) Pub. Date: Dec. 21, 2006

(54) Structured blogging with reciprocal links

(76) Inventor: Andrew Shotland, Pasadena, CA (US)

Correspondence Address: COURTNEY STANIFORD & GREGORY LLP, P.O. BOX 9686, SAN JOSE, CA, 95157, US

(21) Appl. No.: 11/442,105

(22) Filed: May 25, 2006

Related U.S. Application Data
(60) Provisional application No. 60/684,641, filed on May 25, 2005.

(51) Int. Cl. H03M 7/00

(52) U.S. Cl. 341/50

(57) ABSTRACT

Systems and methods for structured blogging with reciprocal links are described below. The systems and methods, referred to herein as Blog systems, provide a structured data format for associating comments and other entries with businesses. This structured data format facilitates data transmission and retrieval of data, particularly by blog managers or servers and search engines. The Blog system also facilitates user data input, such as entering company name and address in the blog, considering that a user selects such information. By adding, for example, the businesses contact information, the blog of the user is made more relevant and informative. The Blog system includes a structured blogging interface that facilitates posting or publishing of blogs and allows a user to go through one user interface rather than having to adapt to the blog posting interface of each third-party blog manager.

### RELATED APPLICATION

This application claims the benefit of U.S. Patent Application No. 60/684,641, filed May 25, 2005.

### FIELD OF THE INVENTION

The present invention is related to electronic advertising and, more particularly, to advertising auction systems and search systems.

### BACKGROUND

The proliferation of electronic devices along with the continued growth of electronic commerce and information exchange has continued at an extreme pace. Consumers therefore continue to turn to the World Wide Web (web) in record numbers to gather information on various goods, services, and activities relating to all aspects of their lives. Weblogs, also referred to as “blogs” or “web logs,” are one example of how people have come to interact to exchange information on the web. A blog is a web-based publication consisting mostly of periodic articles or postings that focus on a particular subject. A conventional blog can combine text, images, and links to other blogs, web pages, and other media related to the topic of the blog. Authoring a blog, maintaining a blog or adding an article to an existing blog is called “blogging,” and a person who posts blog entries or material is called a “blogger.” Blogs have evolved from manually updated components of common websites and online diaries where individual people kept running accounts of their personal lives and posted useful information about their personal experiences. This increasing popularity and evolution of blogs has result in blogs becoming a credible medium of news and other consumer-oriented information. With the ever-increasing popularity of blogs there has arisen a need for tools that facilitate the production and maintenance of blogs by a much larger, less technical, population of people.

### INCORPORATION BY REFERENCE

Each publication, patent, and/or patent application mentioned in this specification is herein incorporated by reference in its entirety to the same extent as if each individual publication and/or patent application was specifically and individually indicated to be incorporated by reference.

### BRIEF DESCRIPTION OF THE DRAWINGS

FIG. 1 is a block diagram of a personal network blog system (Blog system), in accordance with an embodiment.

FIG. 2 is a block diagram of an example structured blogging interface performing the structured blogging features via a browser plug-in, under an embodiment.

FIG. 3 is a block diagram of a client device, under an embodiment.

FIG. 4 shows a block diagram of a PN blog manager, in accordance with an embodiment.

FIG. 5 is a data flow diagram showing how a user may publish blogs to one ore more third-party blog managers and also to the PN blog manager according to an embodiment.

FIG. 6 is a block diagram of display tables illustrating for example the structured blogs, under an embodiment.

FIGS. 7A-7E show how a personal contact network can be created incorporating the blogging features, under an embodiment.

FIG. 8 is an example page informing users that they may download a plug-in or set of program instructions that enables them to post or publish blogs in one or more third-party blog managers and correspondingly in a PN blog manager, under an embodiment.

FIG. 9 is an example page that enables a user to enter a search request, under an embodiment.

FIG. 10 shows an example search result page returned in response to a user's request, under an embodiment.

FIG. 11 shows another example page enabling a user to enter a blog, under an embodiment.

FIG. 12 is another example page enabling a user to register with the PN blog manager via input boxes, under an embodiment.

FIG. 13 is an example page informing users that their registration or membership within the PN blog manager has been successfully completed, under an embodiment.

FIG. 14 is an example page informing users that their blogs have been published or posted successfully, under an embodiment.

FIG. 15 is an example page, for example provided by the PN blog manager, showing blogs stored in the blogs database but also submitted to third-party blog managers, under an embodiment.

FIG. 16 is an example entity/business blog page, for example provided by the PN blog manager, showing three blogs associated with a particular entity, under an embodiment.

FIG. 17 is an example page of a third-party blog manager accessible by a hyperlink, under an embodiment.

FIG. 18 is another example page of a third-party blog manager, under an embodiment.

FIG. 19 is another example third-party blog manager's page showing a link to the PN blog manager, under an embodiment.

FIG. 20 is an example page served by the PN blog manager, under an embodiment.

FIG. 21 is an example third-party blog manager's profile page, for example served by the PN blog manager, under an embodiment.

FIG. 22 is an example page enabling a user to receive RSS feeds, via a plug-in interface independent or incorporated in the structured blogging interface plug-in, under an embodiment.

### DETAILED DESCRIPTION OF THE INVENTION

Systems and methods for structured blogging with reciprocal links are described below. The systems and methods for structured blogging are collectively referred to herein as a Blog system or Blog systems. The Blog system described below generates and promotes a structured data format or formats for associating comments/entries/blog entries with businesses/companies/entities. This structured data format facilitates data transmission and retrieval of data, particularly by blog managers/servers and even search engines. The Blog system also facilitates user data input, such as entering company name and address in the blog, considering that a user selects such information rather than typing it. Furthermore, by adding, for example, the business or entity's contact information, the blog of the user is made more relevant and informative. The Blog system of an embodiment, particularly, the structured blogging interface, facilitates posting or publishing of blogs, by having a user go through one user interface rather than having a user adapt to the blog posting interface of each third-party blog manager. The Blog system also creates a virtual blog network by creating a central hub, such as a personal network (PN) blog manager, which links to one or more third-party blog managers.

Some search engines determine page rank based on the number of links to that page or links by that page to other pages. By using the Blog system of an embodiment, particularly because of reciprocal links, structured blog page rankings and importance may be increased. The Blog system can also be used to give incentive to business to advertise within the system, for example, as a featured business based on the number of blog entries related to their business.

In another embodiment, blogrolls or collections of links to other web logs or blogs are incorporated as part of structured blogs. This list or collection of links is generally used to relate the site owner's interest in or affiliation with other webloggers. Trackbacks may also be incorporated as part of the Blog system of an embodiment. In general, trackbacks are used as a way to comment on a blog remotely or to continue a discussion in another individual's blog or web log. For example, when a user reads an entry in someone's blog (originator's blog) and chooses to write about that entry in his or her own blog, trackback may be used. In this embodiment, a ping or notification is sent to the originator of the blog post, so the originator will know who provided a response about the originator's blog entry. Trackback is a mechanism to let people know that a user has referenced someone else's blog in that user's blog entry. Blogrolls and trackbacks in one embodiment are used to create, update, and/or augment a contact connection affinity network, by creating relationships between bloggers.

The Blog system of an embodiment also enables users to rate and review structured blogs, such as rating the relevancy of a blog as related to a particular category. Furthermore, connections between structured blogs and reviews may be created, for example, if there is an overlap between user A's recommendations and user B's blog recommendations, the Blog system may recommend that user A might enjoy user B's blog. In another embodiment, blogs are rated, for example, based on feedbacks, trackbacks, or rollbacks. In another embodiment, the Blog system of the present invention may be used for revenue sharing opportunities, such as via advertising or community leader programs.

In the following description, numerous specific details are introduced to provide a thorough understanding of, and enabling description for, embodiments of the Blog systems. One skilled in the relevant art, however, will recognize that these embodiments can be practiced without one or more of the specific details, or with other components, systems, etc. In other instances, well-known structures or operations are not shown, or are not described in detail, to avoid obscuring aspects of the disclosed embodiments.

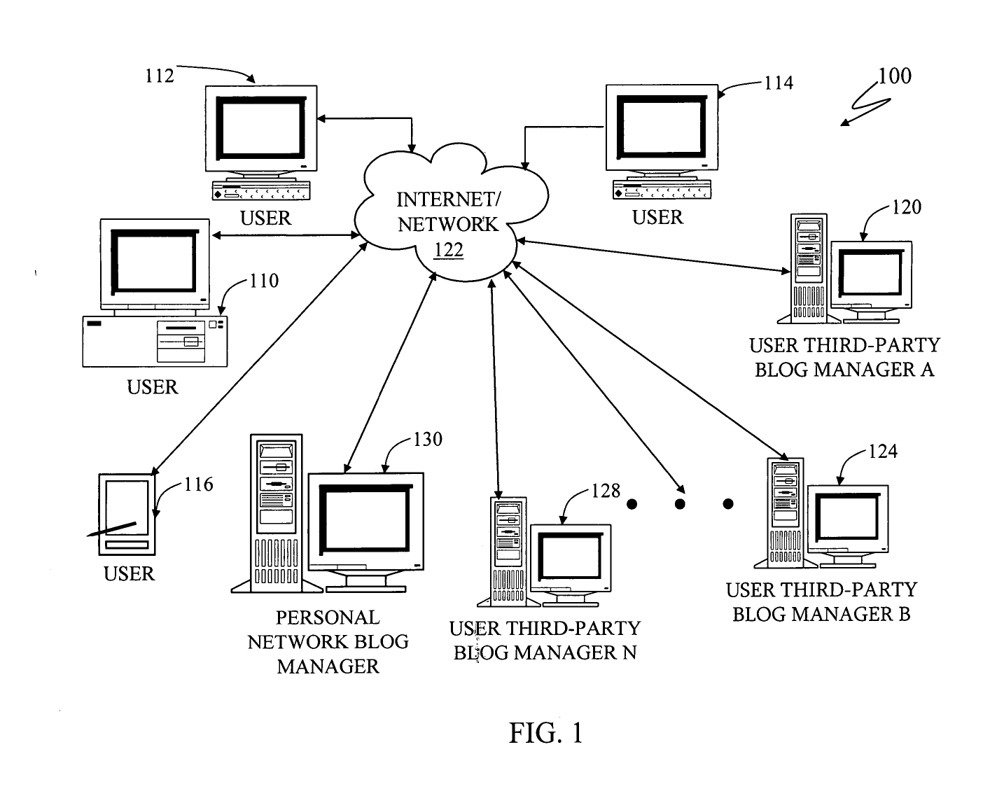

FIG. 1 is a block diagram of a personal network blog system (Blog system) 100, in accordance with an embodiment. The Blog system 100 in general enables users, herein also referred to as bloggers, to provide structured blogs that are automatically transmitted to one or more user-defined third-party blog managers 120, 124, 128 and to a personal network blog manager (PN blog manger) 130. The blogs are structured data, including metadata, that conform to a structured format publicly made available, so that various blog managers and information providers, such as search engines, may easily retrieve information from various third-party blog managers and the PN blog manager 130. The Blog system 100, furthermore, enables users to provide information on blogs about various entities, such as, but not limited to, companies, service and product providers, restaurants, travel spots, vacations, agencies, and any item that may be commented on or reviewed. Such blogs may furthermore be categorized using various categorization schemes and identifiers. The blogs are entered via a structured blogging interface that receives user inputs and accordingly augments and formats the data for transmission to third-party blog managers and/or the PN blog manager. This structured blogging interface may reside in the client or user side and/or the server side, such as within the PN blog manager 130 and/or the third-party blog managers. Users may also accordingly respond to blogs from other users, such that the Blog system 100 keeps track of the series and sequences of associated blogs, similar to how people nowadays may have a trail of email messages link to a particular email. In one embodiment, when a user responds to a blog, a relationship is automatically created, such as a one-degree connection both ways.

The Blog system 100 also provides a reciprocal link, such that a blog written/provided by a user that is transmitted to a third-party blog manger 130 contains or is associated with a link to the PN blog manager, and the blog transmitted to the PN blog manager contains or is associated with a link to the third-party blog manager(s). Thus, reciprocal structured blogs are created with a link to its corresponding reciprocal blog. Such link may include a hyperlink to the website's homepage, to the blog itself, or to any other appropriate page. The Blog system 100, furthermore, enables users to conduct searches of entities, for example businesses local to the user. The blogs transmitted to third-party blog managers are for example augmented with the entity/business contact information and other relevant structured data. The Blog system 100 also enables the users to see blogs and reviews from their personal network contacts, such as view blogs and/or reviews written by their friends or by friends of their friends, for example through the PN blog manager 130 functioning as a web site and/or as a data feeder or transmitter of data feeds, such as syndicated feeds.

Blogs or web logs are online journals, comments, reviews, and any user-entry/input. A blog is typically associated with a date and/or time (date-time), such that a blog server, such as third-party blog managers and the PN blog manager 130, provides blogs in for example reverse chronological order. A blog of the present invention includes other information—not only the information provided by the user—such as user information, entity/business information, date-time stamp, user ID information, and other information that may be related or associated with the information written by the user, including blog manager-related information.

A structured blog of the present invention is for example easily editable and defined to contain various data elements. In one embodiment, these data elements are identified by metadata tags using XML. Various data element-identifying schemes may also be used, such as tags conforming to the HTTP protocol or other specifications or standards available. The structured blog of the present invention is for example defined to include a date-time stamp, the user-entered information, and the entity being reviewed, e.g., business name/ID/reference number. The data elements defined within this structured blog are distinctly identified thus enabling a user to individually modify each of the data elements.

The Blog system 100 in an embodiment includes a PN blog manager 130, for example a server, wherein several client or user devices, for example, computer devices or terminals 110, 112, 114, 116, are coupled to the PN blog manager 130 via a wired or wireless network 122, such as the Internet, a wide area network, a local area network, and/or an intranet. The PN blog manager 130 for example functions as a website and may include one or more servers. The PN blog manager may also function as a transmitter of data feeds.

Users may have one or more third-party blog managers that they access to post blogs. Typically, these third-party blog managers are websites and/or data transmitters. The website www.blogwise.com, for example, functions as a directory that contains links to various blog servers or providers. In an embodiment, the users 110, 112, 114, 116 are coupled to their respective user third-party blog manager(s) 120, 124, 128 via a data network, which may be the same network 122, such as the Internet.

In general, the users of the Blog system 100 connect with the PN blog manager 130, which serves up web pages, transmits requested data—e.g. data feeds, and/or implements some of the features of the present invention. The data received by client devices from the PN blog manager 130 are accordingly processed and presented in a user interface. These client devices 110, 112, 114, 116 may be computers or other network-enabled devices, including, but not limited to, Web-enabled wireless phones, personal digital assistants (PDAs), smart phones, Internet-enabled game devices, e.g., XBOX™ and PlayStation™, and interactive televisions. These client devices enable users to interface with the PN map manager 130 and/or the third-party blog managers, using various mechanisms, including, but not limited to, keyboard entries, voice-activated commands, touch-tone phone interfaces, and touch screens.

The Blog system 100 of an embodiment is designed to facilitate posting blogs, reviewing and editing blogs, as well as provide other information, such as advertisement-related information. In another embodiment, the PN blog manager 130 is capable of sending data or data feeds, such as through extensible markup language (XML) files, including syndication feed formats, e.g., really simple syndication and/or RDF site summary (RSS) and ATOM format. Information about ATOM may be found, for example, in www.atomenabled.org website.

One of ordinary skill in the art will realize that the structured blogging features of the present invention may be implemented in a number of ways. For example, the database containing the blogs may be local to or remote from the blog publishing or maintenance module. Furthermore, the formatting of data into a structured blog format may be handled by the client—such as a browser plug-in or a stand-along program outside of a browser, by the server, e.g., third-party blog manager or the PN blog manager—such as via a set of program instructions, or by the client and the server interfacing with each other. In addition, the publishing or posting of the structured blogs with reciprocal links may be handled by the client side and/or the server side. For example, the user/client side transmits the formatted structured blogs to the third-party blog managers and the PN blog manager. In another embodiment, raw data, using standard HTTP post commands, are sent by the user/client side to the PN blog manager. The PN blog manager formats the data into a structured blog data format and stores that structured blog in a local or remote blog database. The PN blog manager also handles the transmission of the structured blog with the appropriate reciprocal link to the appropriate third-party blog manager.

In another embodiment, the client posts raw data to the third-party blog manager using standard HTTP post commands. The third-party blog manager, for example, via a server-side plug-in, formats the data into a structured blog data and handles the transmission of the structured blog with appropriate reciprocal link to the PN blog manager. In another embodiment, raw data are transmitted by the client to an intermediate blog manager, which in turn formats the data into a structured blog data and then transmits the structured blog to the third-party blog manager and the PN blog manager, for example, using the file transfer protocol. (FTP). An example of such intermediate blog manager implementation is available from BLOGGER™ of www.blogger.com. This implementation, however, has to be modified to accommodate the novel features of the present invention. One of ordinary skill in the art will realize that other client-server architectures may be implemented and yet still be in the scope of the present invention. Furthermore, various mechanisms to implement some features of blog publishing are available, for example, from TYPEPAD™ (www.typepad.com), BLOGGER™ (www.blogger.com), WORDPRESS (www.wordpress.org). and LIVEJOURNAL™ (www.livejournal.com). These available features, however, have to be modified to handle the novel features of the present invention.

In one example architecture, a plug-in is created to implement the features of the present invention. This plug-in interfaces with the blog publishing module, i.e., code or set of program instructions, made available by WORDPRESS™, www.wordpress.org. This plug-in, including the available source code, is installed and executed on a user third-party blog manager. In this example embodiment, a user posting a structured blog to the third-party blog manager is enabled to automatically post a reciprocal structured blog to a PN blog manager.

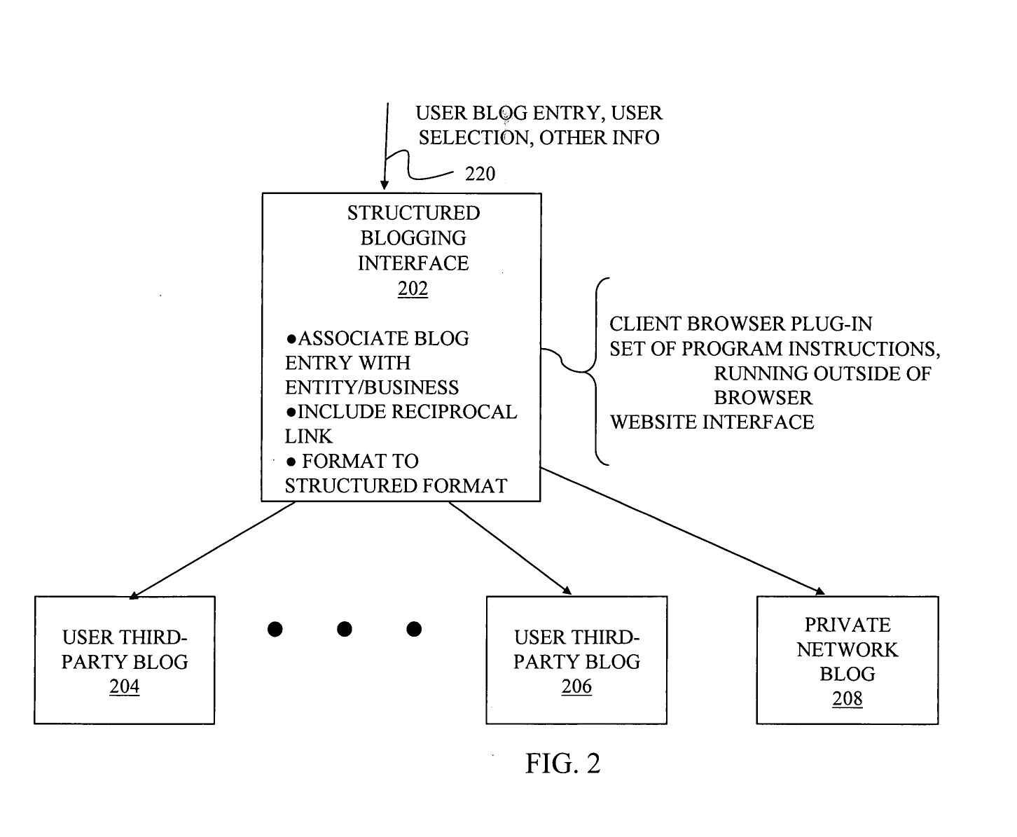

FIG. 2 is a block diagram of an example structured blogging interface performing the structured blogging features via a browser plug-in, under an embodiment. The structured blogging interface 202, although for example implemented as a client browser plug-in or add-on, may be implemented in many ways, as one of ordinary skill in the art will realize, e.g., as a set of program instructions running outside of a web browser—, a stand-alone software program or a dynamic link library interfacing, for example, with the PN manager, or as a client-server architecture system, where the PN manager functions as a web server serving web pages to a client web browser.

Via the structured blogging interface 202, a user may enter data, e.g., blog entry/comment, user selection, and other user-provided information. The structured blogging interface 202 is also able to receive data from other sources, from the PN blog manager 130. The structured blogging interface 202 in general performs many functions further discussed herein, including associating user blog entry with corresponding entity/business, generating reciprocal links, and formatting data into a structured data. The structured blogging interface thus accepts and generates a structured format data set that is transmitted as a user third-party blog 204, 206 and/or a private network blog 208. A user-third-party blog is generally transmitted to a third-party blog manager, while a private network blog 208 is generally transmitted to a PN blog manager 130.

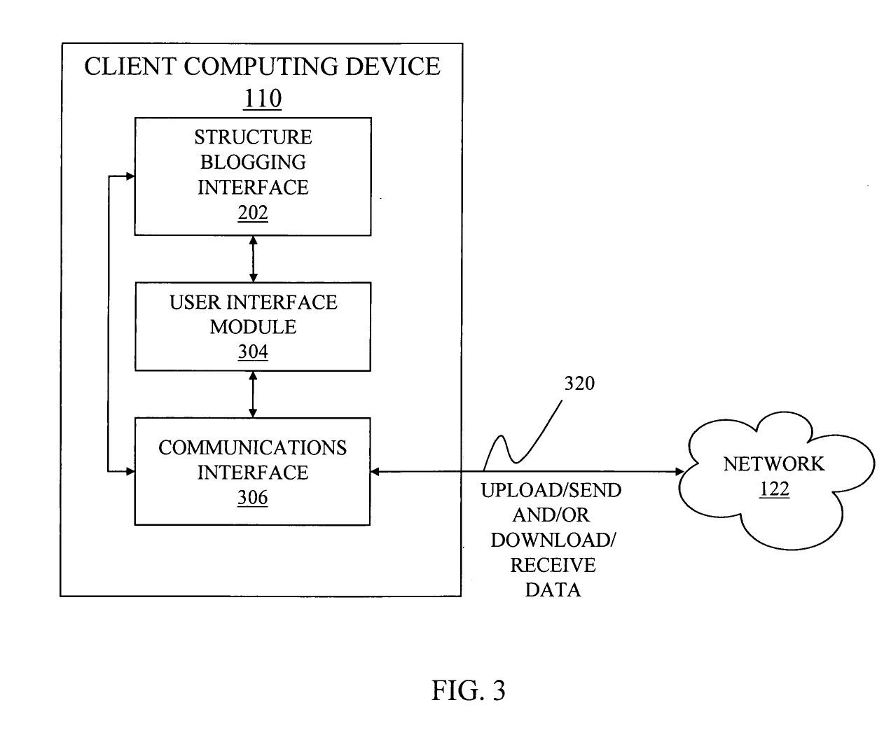

FIG. 3 is a block diagram of a client device 110, 112, 114, 116, under an embodiment. The Blog system 100 for example has the structured blogging interface 202 residing on the client computing device 110, for example as a browser plug-in or add-on. This plug-in interfaces with a user interface that facilitates user blog entry and publishing to third-party blog managers and to the PN blog manager. Such plug-in may be written in various programming languages and implemented using various software engineering techniques, as known to those of ordinary skill in the art.

The client computing device 110 for example includes a structured blogging interface (SBI) 202, a user interface module 304, and a communications interface 306. The user interface module 304 handles user presentation, under the control of the structured blogging interface 202, that is, the SBI 304 enables users to interface with the Blog system 100. The presented user interface may be visual or auditory, or even both. For example, a user may enter search requests via stand-alone window programs or web pages within an Internet browser and enter commands via voice-commands, dual tone multi-frequency signals (DTMF), keyboard entries, touch-screen entries, mouse clicks, and the like. In an embodiment, the user interface 304 is a web browser presenting pages and accepting input from users. The communications interface 306 enables a user to communicate 320 with the Blog system in general and particularly to third-party blog managers 120, 124, 128 and the PN blog manager 130.

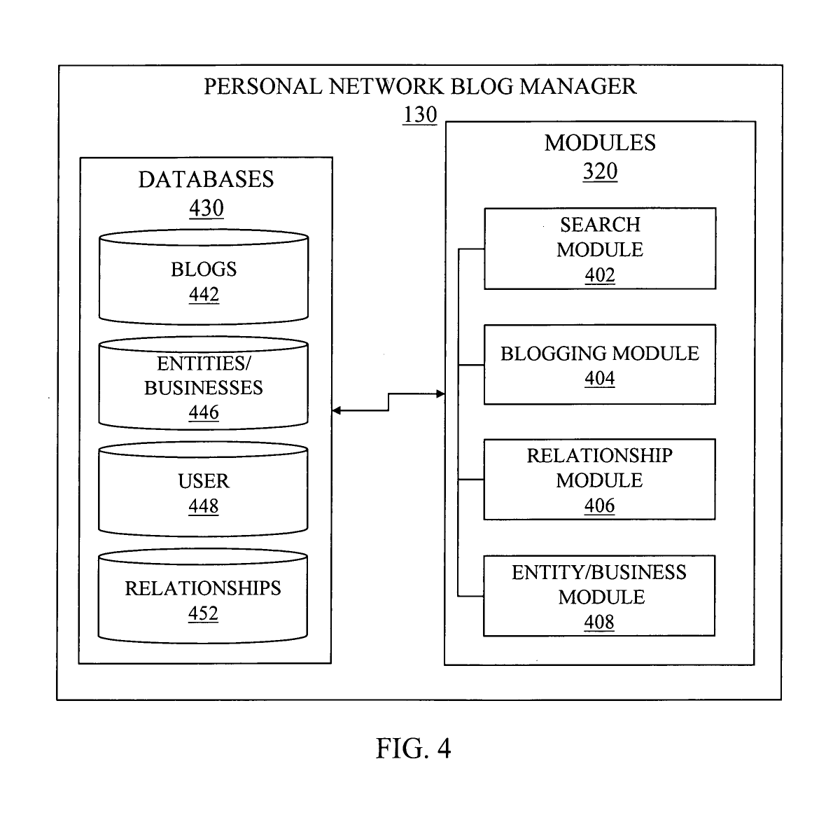

FIG. 4 shows a block diagram of a PN blog manager 130, including example modules 420 and databases 430, in accordance with an embodiment. These various modules 420 may be replicated and/or distributed over one or more servers, and in general are sets of program codes, functions, processes, program instructions, and/or applications that are executable by computing devices, for example computers, to perform the features of the present invention. These modules interface with each other.

The PN blog manager 130 also for example includes one or more data stores containing data related to blogs 442, businesses or entities 446, users 448, and for example also relationships 452 between users. These data stores may be databases, such as relational database management systems (RDBMs), object-oriented database management systems, linked lists, arrays, flat files, comma-delimited files, and the like. Data, however, are for example stored in RDBMS.

The blogs database 442 generally contains structured blogs provided by users. The entities/businesses database 446 stores information about entities, and in particular companies or businesses that may be commented or reviewed by users. In one embodiment, a user may enter a blog within the system without associating that blog with a particular entity, e.g., a company. Blogs, for example, may be entered by just categorizing them under a particular topic, such as plumbing, parenting, and/or education. The entities/businesses database 446 may include name, address, phone number, email address, type of service or product, and/or county. The users database 448 stores information about registered users, such as user name, user password, first and last name, email address, and address.

The PN blog manager 130 in an embodiment also functions as a personal contact network manager, wherein users may define relationships between users, such as being direct friends or friends of friends. In this embodiment, users may selectively, for example, only view blogs from direct friends or from friends of friends. The relationships database 452, thus, for example contains information about the various relationships between users. Other databases, not shown, may also be present within the Blog system 100, which may include, for example, databases containing topic areas or blog categories, ratings, zip code boundaries, and advertisements.

The PN blog manager 130 generally includes a search module 402, a blogging module, 404, a relationship module 406, and an entity/business module 408. The search module 402 generally receives the search requests from users 110, 112, 114, 116 via the network 122. The blogging module 404 generally handles the maintenance of blogs submitted by users, such as storing structured blogs in a data store, deleting blogs, editing blogs, and/or keeping blog statistics, if appropriate. In another embodiment, the blogging module performs the formatting of data received from the user into structured blog data. The relationship module 406 handles the maintenance of the relationships database 452, such as reading and updating that database, performing procedures, such as stored procedures, to determine relationships, and/or interfacing with the search module 402. The entity/business module 408 generally performs the functions related to entities or businesses within the Blog system 100.

The Blog system 100 may be adapted to handle other features. For example, the blog system may be incorporated as part of a recommender system, a system that provides reviews by friends and friends of friends, a map searching system, an advertising venue system, and the like. Modules and databases designed to handle additional features are for example incorporated as part of the PN blog manager 130. One of ordinary skill in the art will realize that modules incorporated in the PN blog manager may vary depending on system implementation and design.

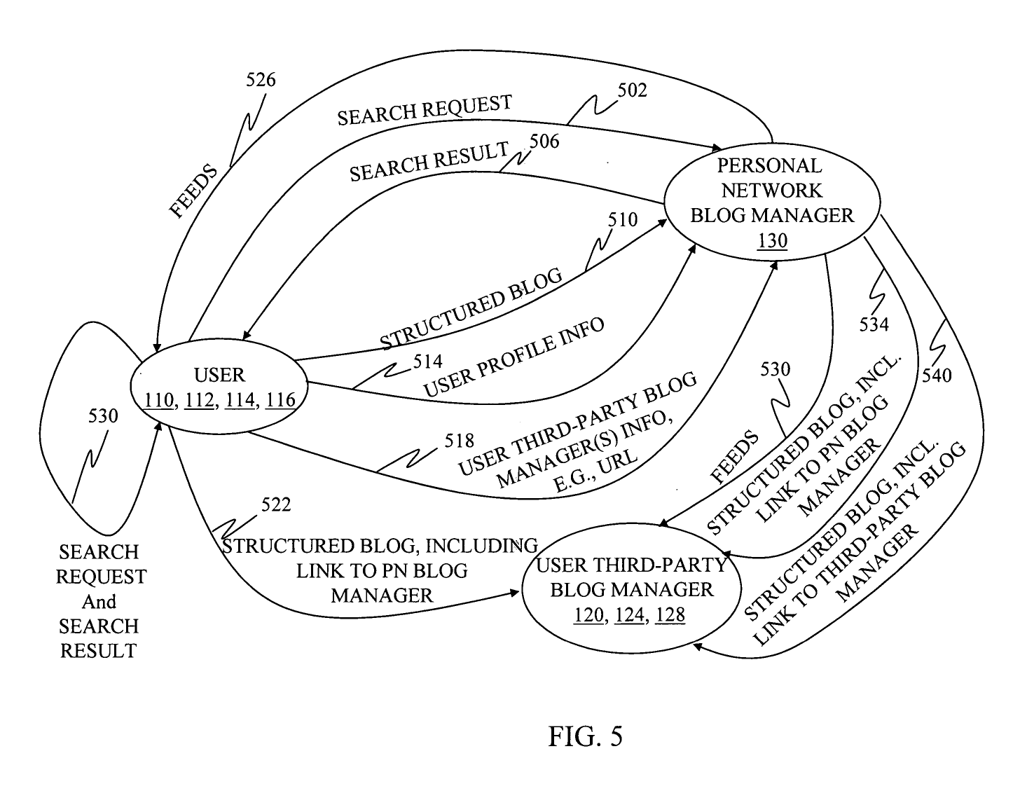

FIG. 5 is a data flow diagram showing how a user may publish blogs to one ore more third-party blog managers and also to the PN blog manager according to an embodiment. In this data flow, the user desires to post blogs to one or more third-party blog managers. The user initiates this process, for example, by clicking an icon on the user's web browser that activates the structured blogging interface features. Clicking the icon brings up a user interface enabling a user to search for entities/businesses to comment on or review, meaning to provide a blog entry.

A user enters a search request, for example, enters “restaurants” located in zip code “90017.” In one embodiment, the user 110, 112, 114, 116 sends this search request 502 to the PN blog manager 130. This request is received via the client's user interface 304 (FIG. 3), e.g., as a web page, and submitted as a request using data network protocols, such as hypertext transfer protocol (HTTP). The PN blog manager 130 responds to such request by sending a search result 506 back to the user 110. Generally, the PN blog manager searches the entities/businesses database 446. In another embodiment, the PN blog manager requests data from another server that stores or interfaces with an appropriate entities/businesses database. In an alternative embodiment, the search is not transmitted to the PN blog manager 130, but is handled by the client computing device, for example by the structured blogging interface 202. In this embodiment, the entities/businesses database is resident in the client's computing device, such that when the user enters a request 530 via the user interface module 304, the structured blogging interface 202 queries a local database to respond to the user's request 530.

Based on the search result, a user selects an appropriate entity/business/company and enters a blog entry related to the selected entity/business 510. The search result 506, 530 for example includes information identifying the businesses, such as, the entity ID number or company ID number which for example identifies “Willy's Plumbing” to the PN blog manager 130. If the appropriate entity, however, is not found, the user in one embodiment is enabled to enter such entity information, which is then accordingly processed and stored in the appropriate database. User profile information 514, e.g., via cookies or by entering user profile information via a web page, is also for example sent to the PN blog manager 130 and/or the third-party blog managers 120, 124, 128.

In one embodiment, the structured blogging interface is designed to automatically post blogs to user-identified third-party blog managers 120, 124, 128. The user is thus queried—may be part of a user profile information resident on the user's client computing device—for the URL address, for example, of such third-party blog managers. Other information related to the third-party blog managers, such as user names, and/or passwords, may also be sent 518 to the PN blog manager 130.

In an, embodiment, the user, particularly, the user's client computing device directly transmits the structured blog to the user's third party blog manager 120, 124, 128. This blog transmitted 522 is a structured blog, formatted and generated, for example by the structured blogging interface. This structured blog, for example includes all information to enable publishing or posting to the user's third-party blog manager, and also includes a link to the PN blog manager.

In an alternative matter, the structured blog, including the link to the PN blog manager, is sent 534 by the PN blog manager 130 instead of the user's computing device. In another embodiment, the structured blog, including the link to the third-party blog manager 540, is sent by the user third-party blog manager. In one embodiment, the PN blog manager is able to respond to syndication requests from users 526, as well as other third-party blog managers 530. In an embodiment, such feeds are formatted using the RSS or ATOM format.

As described above, a user entering a blog in the present invention generally for example results in at least two structured blogs being created—one structured blog, with a link to the PN blog manager, associated with the third-party blog manager and another structured blog, with a link to that third-party blog manager, associated with the PN blog manager. These two structured blogs are reciprocal blogs and each contains a link referencing each other. In another embodiment, a structured blog is posted without an accompanying reciprocal structured blog, i.e., a structured blog entry is posted to a third-party blog manager without being posted to a PN blog manager, or vice versa.

In an embodiment of the invention, a structured blog may be modified. A modification of a structured blog is for example synchronized such that changes to a structured blog automatically trigger an update to the corresponding reciprocal structured blog. For example, if a user edits a structured blog associated or stored in the PN blog manager, the blog system of the present invention, also automatically updates the reciprocal structured blog associated with or stored in the corresponding user third-party blog manager. In another embodiment, an update is not automatically performed but rather a request for an update is sent to the appropriate blog manager, e.g., PN blog manager or third-party blog manager.

The structured blog of the present invention has data elements distinctly identified thereby facilitating identification and indexing of data elements. This feature provides a mechanism for spider or robot programs crawling the Internet or the World Wide Web to easily extract and identify data as well as provides search engines or data feeders/transmitters a way to index and identify particular data elements thereby also providing more relevant responses to search or data requests. These provisions equally apply when such structured blogs are submitted to search engines as well as to data feeders/transmitters. For example, the structured blogs are fed or transmitted using XML, thereby facilitating presentation and reading by data aggregators, such as RSS-aware or syndication-capable programs. Conventional search engines include GOOGLE™ (www.google.com). FEEDSTER, INC.™ (www.feedster.com), and TECHNORATI™ (www.technorati.com).

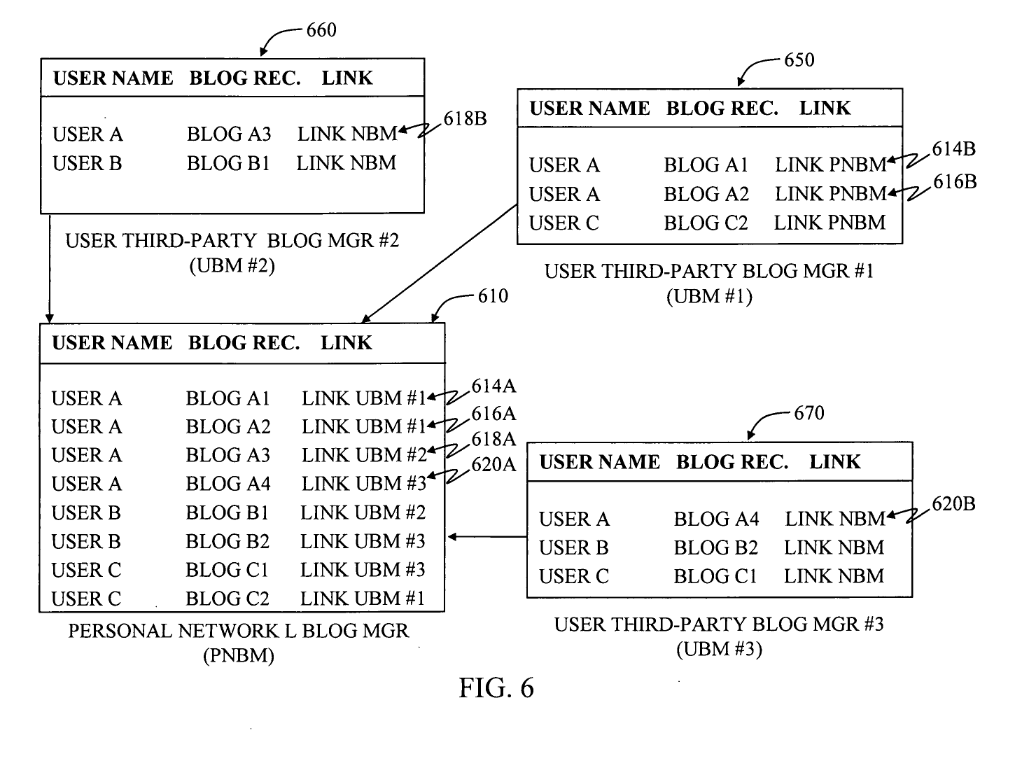

FIG. 6 is a block diagram of display tables illustrating for example the structured blogs, under an embodiment. In this embodiment, when a user posts or publishes a structured blog at a third-party blog manager, a structured blog is also correspondingly published at the PN blog manager 130. In this example embodiment, User A wants to publish blogs in three third-party blog managers—UBM #1 (represented by the top right table 650), UBM #2 (represented by the top left table 660), and UBM #3 (represented by the bottom right table 670).

User A has entered four blogs A1 614B, A2 616B, A3 618B, and A4 620B. These blogs are for example all entered using the structured blogging interface and user interface module of the present invention. This way, a user may post or publish blogs generally using only one interface regardless of the third-party blog manager. As discussed above, this may be performed using a browser plug-in, a stand-alone set of program instructions, or via a website, for example. In one embodiment, the user is able to selectively decide for each blog the third-party blog manager(s) with which to post/publish. A blog herein is also referred to as a blog post or a blog entry.

Blogs A1 and A2, including the reciprocal links to the PN blog manager, are posted to the user's third-party blog manager 614B, 616B UBM #1 650; while Blogs A3 618B and A4 620B are posted at third-party block managers UBM #2 660 and UBM #3 670, respectively. Correspondingly, Blogs A1 614A, A2, 616A, A3 618A, and A4 620A are posted in the PN blog manager 610 with links to the appropriate third-party block managers.

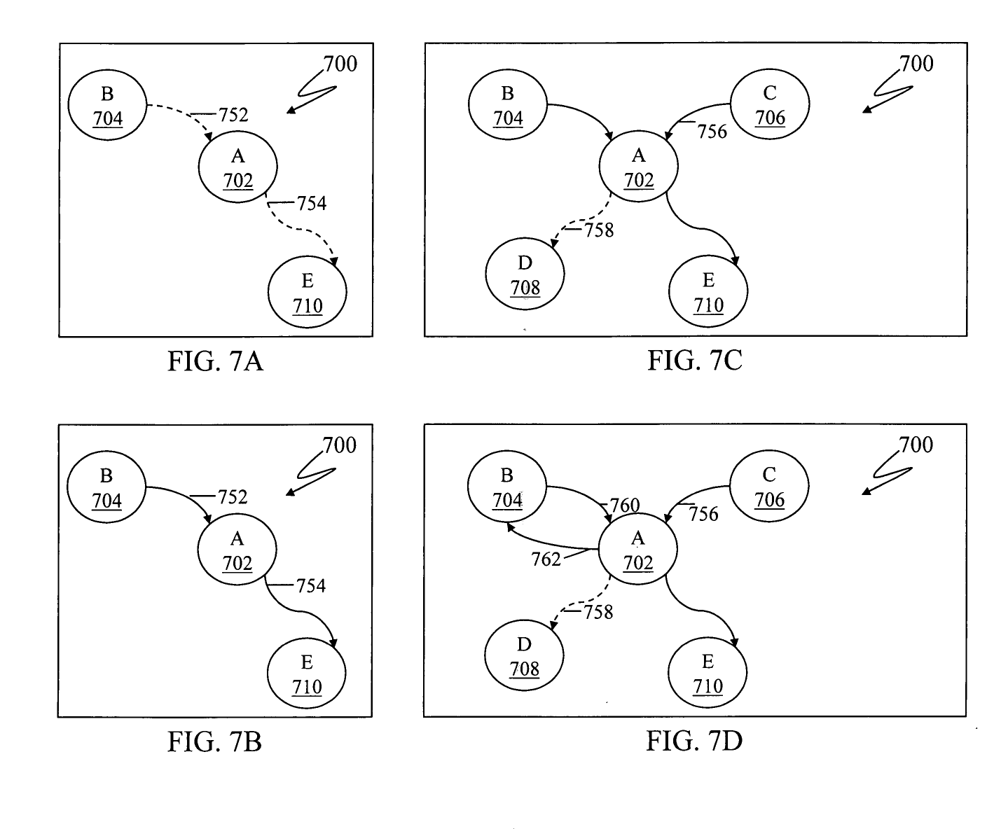

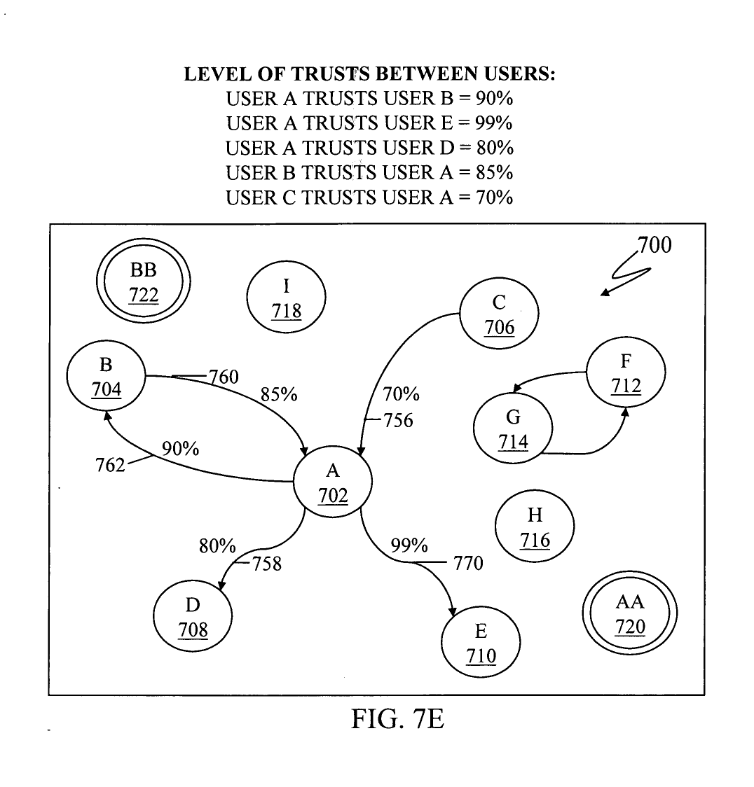

FIGS. 7A-7E show how a personal contact network can be created incorporating the blogging features, under an embodiment. In particular, FIG. 7E is a graphical illustration of a user network 700 comprising a plurality of users 702, 704, 706, 708, 710, 712, 714, 716, 718, 720, 722. Users A, B, C, D, E, F, G, H, I are registered users while Users AA 720 and BB 722 are anonymous users of the Blog system. Users AA and BB are anonymous because they have not registered, such as by providing user information, e.g., user name and password and/or email address. Anonymous users may also participate in the features of the present invention, such as by providing blogs and having such blogs be also presented to users.

In this example network, a contact connection affinity network is defined within the Blog system 100. A contact connection affinity network generally defines the relationships between users, such as whether they are immediate or direct friends or are friends of friends. Users thus may in one variation are able to see blogs of friends or blogs of friends of friends. In one embodiment of the invention, the user network only contains a contact connection affinity network type—meaning the users may be interrelated directly or indirectly by indicating whom they know.

It is possible, however, that a registered user, e.g., Users H 716 and I 718, does not have any relationship with any other user. Furthermore, the network 700 may be disjointed such that pockets of connected subnetworks exist, e.g., subnetwork created by Users A 702, B 704, C 706, D 708, and E 710 and the other subnetwork created by Users F 712 and G 714. In this example embodiment of the invention, a relationship or affinity with another user is only established when an invitation to join an affinity network is accepted. In another embodiment, not shown, acceptance of an invitation is not necessary to establish a relationship.

Each user is graphically shown as a node 702, 704, 706, 708, 710, 712, 716, 718, 720, 722 with an accepted relationship shown as a solid line between two users and an unaccepted relationship shown as a dashed line. The origin of a line indicates the inviting user and where the line ends with an arrow shows the invitee.

Referring to FIG. 7A, User B 704 invites User A 702 to establish a relationship; User A, however, has not accepted the invitation, as shown by the dashed line 752. User A 702 has also invited User E 710, but User E 710 has not accepted the invitation. In this example embodiment, the users have not established a relationship with each other. Other embodiments, however, does not require invitations and acceptances to establish relationships.

FIG. 7B is similar to FIG. 7A but illustrating the two accepted relationships as shown by the solid lines 752, 754. In this embodiment, the relationships between User B 704 and User A 702, and between User A and User E 710 have been established. User A is one connection away from User B, while User E is one connection away from User A. Users A and B are directly connected, similar to Users A and E. User B 704, however, is indirectly connected to User E 710, in this case, two connections away from user E 710. The connection number or value may be obtained by adding the number of connections between the two users—between Users B 704 and A 702, one connection, and between Users A 702 and E 710, one connection, for a total of two connections.

Generally, users invite other users to become part of their personal contact network. In this example embodiment, this is based on whether a user knows another user, meaning User B 704 invited User A because User B knows User A, and User A 702 invited User E 710 because User A knows User E. User B 704 knows User E 710 indirectly via User A 702, meaning User E is a friend of a friend, meaning a friend of User A.

FIG. 7C shows two more users being added to the network—Users C 706 and D 708. In this example, User C 706 issued an invitation to User A 702, which was accepted as shown 756. User A has also issued an unaccepted invitation to User D 708, shown by the dashed line 758. User C 706 is one connection away from User A 702, while User C 706 is two connections away from User D 708, User E 710, and User B 704.

FIG. 7D is similar to FIG. 7C, but in this case User A 702 has also issued an invitation to User B 704, which User B accepted, shown by the solid line 762. The relationship between Users A 702 (inviter) and B 704 (invitee) denoted herein by AB, and the relationship between Users B (inviter) and A (invitee), denoted by BA, may be the same or different, depending on system design.

In one embodiment of the invention, the relationship is not only defined by the number of connections but also by a weight such as those shown in FIG. 7E. The relationship or affinity weight, in another embodiment, is assigned a default value, for example, based on the number of connections. This value may be adjusted by the user and/or by the Blog system 100. Attributes affecting relationship or affinity weight, for example, may include how much, for example, User A trusts B, i.e., a numerical trust value, the similarity of user's blog ratings, the geographical distance between two users, etc.

In one embodiment, the relationship is based on a reputation measurement or rating. The reputation rating is intended to reflect how trustworthy or reliable users are and their recommendations. Optionally, this personal reputation rating or score is viewable by other users via the Web site. In another embodiment, each user is assigned a unique reputation rating with respect to each other. The reputation rating may be assigned or calculated using one or more of the following attributes, as well as other relevant attributes:

Number of users in the system;

Number of accepted friends;

Ratio of connection invitations sent versus connection invitations accepted (in one embodiment, a connection invitation is defined as one user asking to share information with another);

Number of validations, e.g., responses to blog entries.

FIG. 7E is similar to FIG. 7D but showing that User D 708 has accepted the relationship invitation, shown by the solid line 758. In this example contact connection affinity network of affiliates, User A 702 trusts User B's recommendation or User B 704 ninety percent (90%) of the time, User E's 710 recommendations ninety-nine percent (99%) of the time, and User D's 708 recommendations eighty percent (80%) of the time. On the other hand, User B 704 trusts User A 702 eighty-five percent (85%) of the time, while User C 706 trusts User A 702 seventy percent (70%) of the time. In this example embodiment, ninety-nine percent (99%) is the highest level of trust a user may bestow upon another user. In this example embodiment, the relationship is influenced by the number of connections between users and the weight—level of trust—between the users.

One skilled in the art will recognize that various ways to calculate relationship weight, including the attributes used, may be implemented within the knowledge system 100. In this example embodiment, the relationship between Users A and B 762 (AB) is 90%, between Users B and A 460 (BA) is 85%, between Users A and D 758 (AD) is 80%, Users A and E 470 (AE) is 99%, and Users C and A 756 (CA) is 70%. In one example embodiment of the invention, the relationship between Users C 706 and D 708 is derived by obtaining an average, which is 75%. Thus, in one example embodiment, the relationship weight between Users C and D is 75%. Other mechanisms of calculating the relationship weight may also be implemented. In an embodiment, the relationship or affinity is represented as a real number.

Other types of relationships may be implemented in the personal network of the present invention. For example, a familial affinity network may be implemented where relationships are based on blood or marriage relationship, such as mother, father, sibling, second cousins, etc. Depending on the relationship, the weight may be different.

Using the above example personal network, the PN blog manager of the present invention enables users to filter and search blogs based on relationships defined within a system. Furthermore, filter or searches may be based on user profile information, for example, the zip code where a user lives. Furthermore, blogs presented to users may be based on various conditions such as where the user resides—showing blogs of users living within the same county, or having the same profession—showing all blogs posted by users working in the construction business. In another embodiment, a relationship is automatically established between two users when one of the users responds to the blog entries posted by the other user.

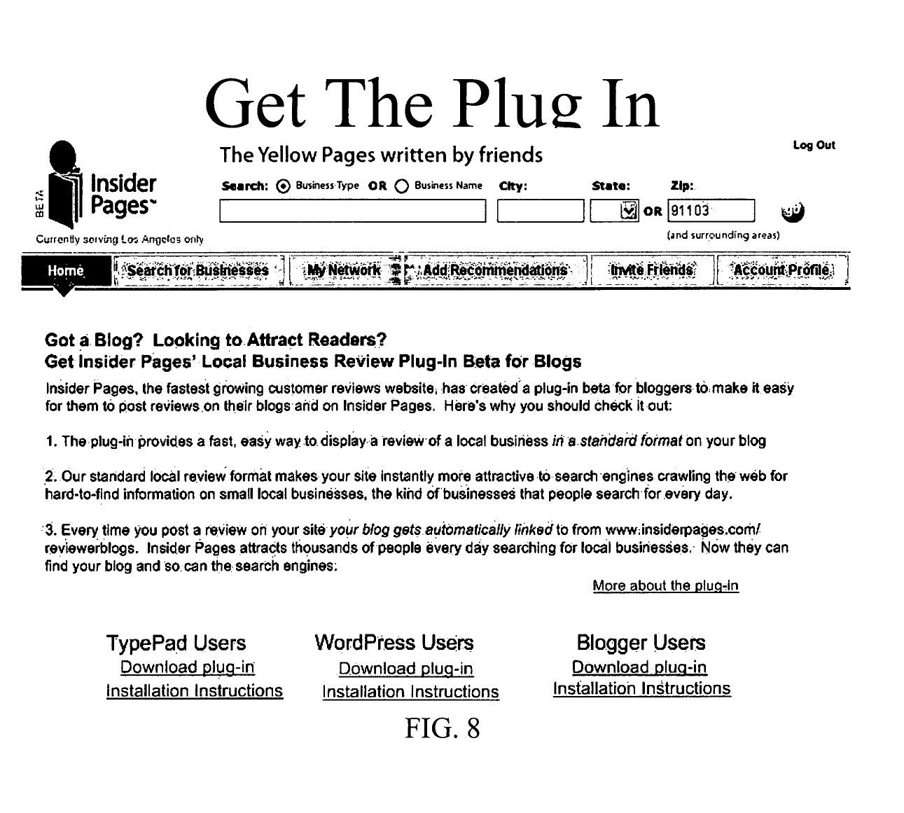

FIGS. 8-23 are example presentations illustrating some of the features of the present invention.

FIG. 8 is an example page informing users that they may download a plug-in or set of program instructions that enables them to post or publish blogs in one or more third-party blog managers and correspondingly in a PN blog manager, under an embodiment. This plug-in for example performs the functions of a structured blogging interface. Examples of conventional third-party blog managers/servers include TypePad (www.typepad.com) and Bloggers (www.bloggers.com). In one embodiment, users are provided incentives to download this structured blogging interface plug-in. Such incentives include credit points, monetary compensation, and more website accessibility.

In another embodiment, the plug-in interface also functions as a data feed aggregator that is able to receive syndicated feeds or other various data formats, and accordingly presents such data feeds in a user interface. A data feed aggregator is also called a news aggregator and may also be an RSS reader, which accepts RSS feeds. In one embodiment, the data feed aggregator receives data feeds from the PN blog manager and/or one or more third-party blog managers. For example, a user may set certain conditions on which to receive feeds, such as only receive data feeds from their direct friends, feeds only from a particular third-party blog manager UBM #1, and feeds from a weather blog manager.

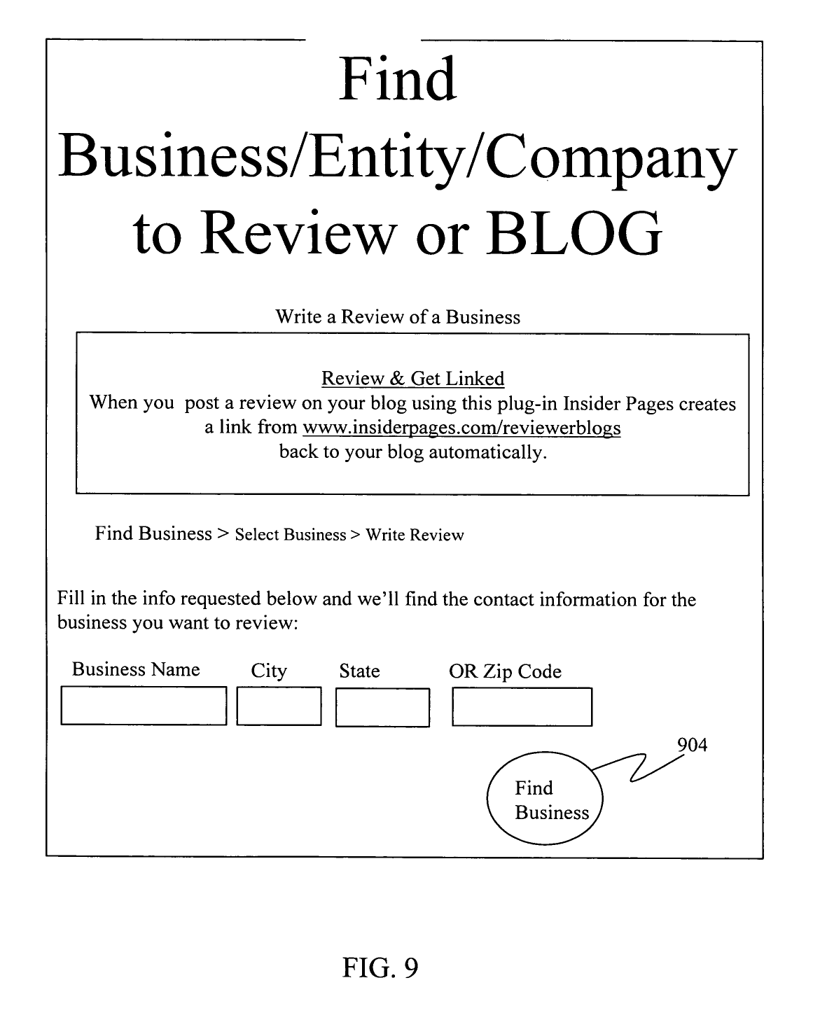

FIG. 9 is an example page that enables a user to enter a search request, under an embodiment. This page is presented via the user interface module 304 for example interfacing with the structured blogging interface 202. In one embodiment, this page is displayed by clicking an icon in the user's desktop or an icon within the web browser. A user, for example, enters a business name, city, state, and/or zip code in the appropriate input boxes, and then submits such request by hitting the “Find Business” button 904. This request depending on system design and implementation may be sent to the structured blogging interface within the client's computing device or to the search module 302 of the PN blog manager 130.

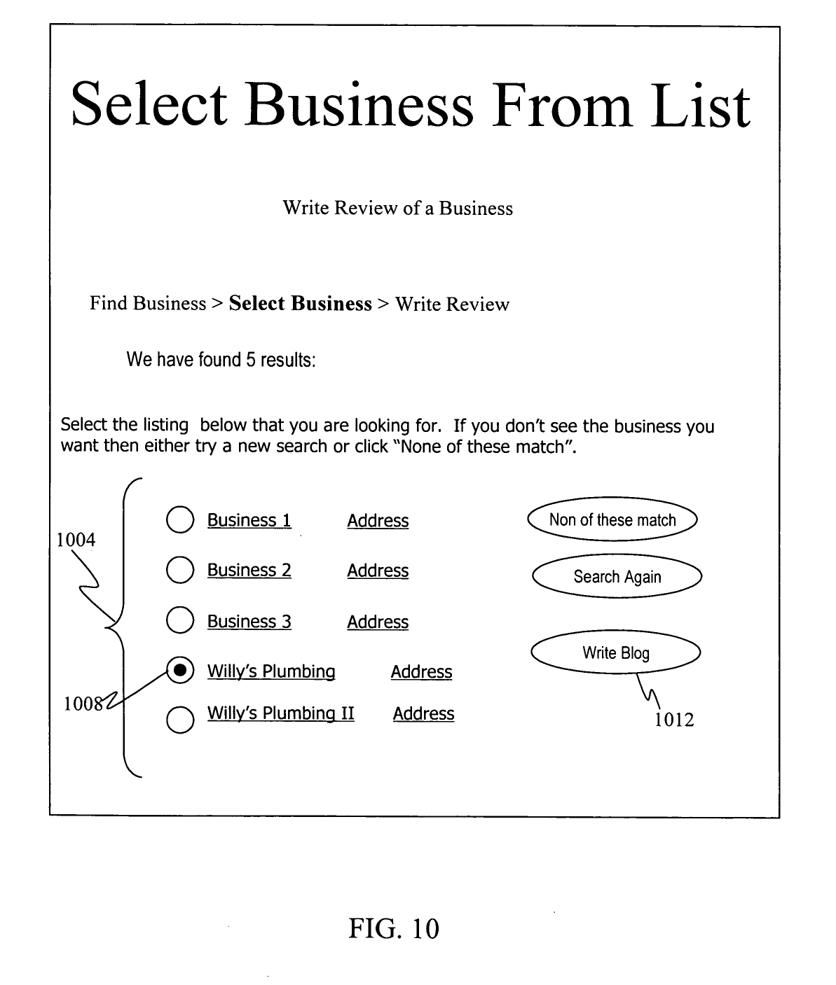

FIG. 10 shows an example search result page returned in response to a user's request, under an embodiment. This page includes a number of listings 1004, which a user may select to write a blog by clicking the desired radial button 1008 and by clicking the “Write Blog” button 1012.

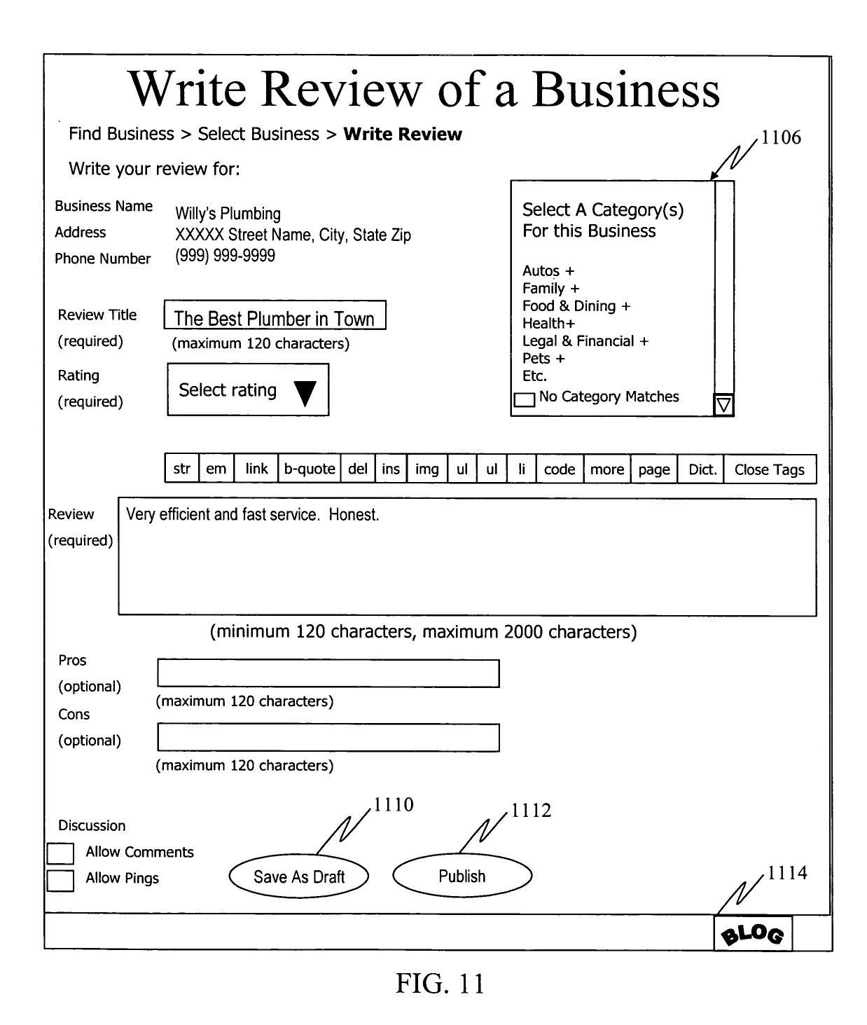

FIG. 11 shows another example page enabling a user to enter a blog, under an embodiment. The page also includes information for example included as part of the structured blog data or record. For example, if the user selects Willy's Plumbing 1008 from the previous screen (FIG. 10), a user may provide a blog for such entity/business through this example interface. For example, the user also provides a category or topic area 1106 so that the blog may accordingly be categorized. The user also has the option to locally save the blog as a draft by pressing the “Save As Draft” button 1110, alternatively publishing or posting 1112 the blog associated with “Willy Plumbing” to the user-defined one or more third-party blog managers and the PN blog manager 130. The manner and timing of requesting where the blog should additionally be posted aside from the PN blog manager may be obtained via web pages, not shown.

An icon 1114 activating the structured blogging features of the present invention is installed in the web browser when the plug-interface was installed. FIG. 9, for example, may have been activated by having the user click on the Blog icon 1114.

The structured blog data, in an embodiment, includes the entity or business name, title, the review—the blog/review/comment entered by the user, category, pros, cons, and a rating—for example represented as a one to five star rating. Once the user decides to publish the blog, the structured blog data is transmitted to the third-party blog managers and the PN blog manger. The blog structured data for example also include the reciprocal link, such as a link to the PN blog manager if the structured blog is posted to a third-party blog manager and a link to the one or more third-party blog managers when the structured blog is posted to the PN blog manager. The link is for example a hyperlink to a URL address, which may be a home page, a particular subdomain, or a particular page. Header data, such as those including parameters, may also accordingly be used.

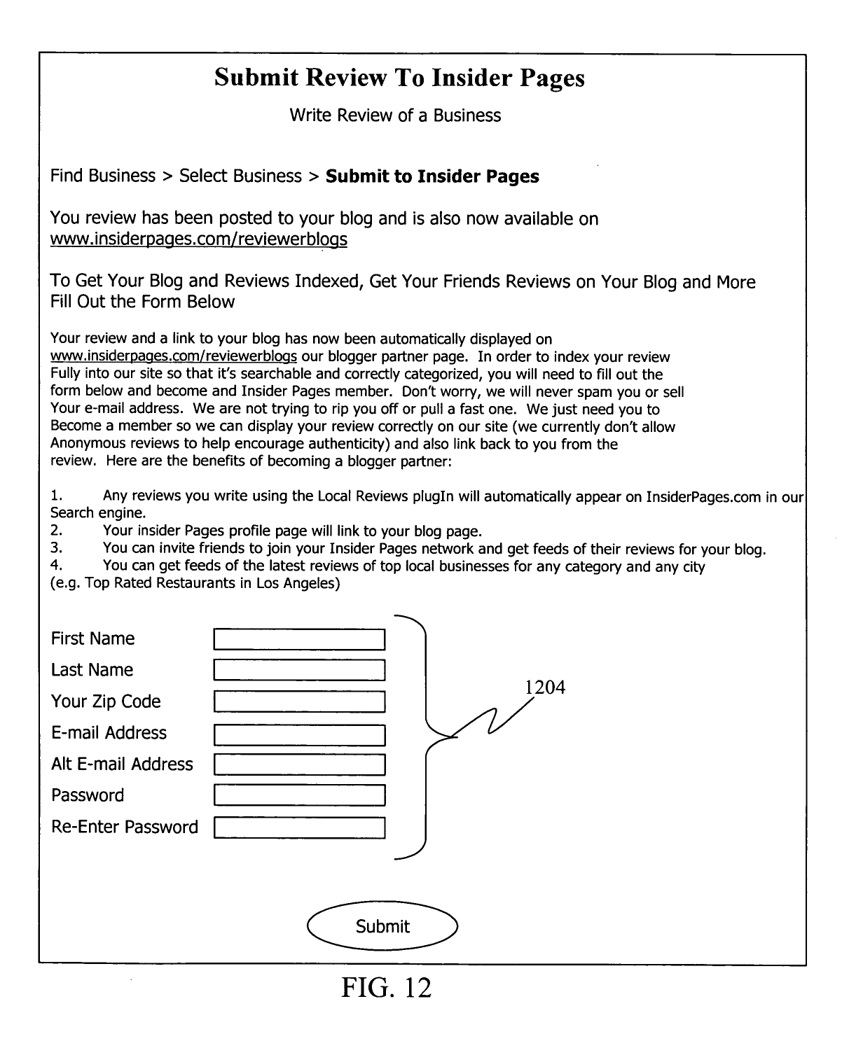

FIG. 12 is another example page enabling a user to register with the PN blog manager via input boxes 1204, under an embodiment. One feature of the present invention enables a user to post blogs in the PN blog manager regardless of whether such user registers with the PN blog manager 130. A registered user, however, is for example granted more functions and features as compared to anonymous users. For example, structured blogs from anonymous users are not indexed for finer searching or their blogs may be posted in a general blog page but not posted under the business/company associated with their structured blogs.

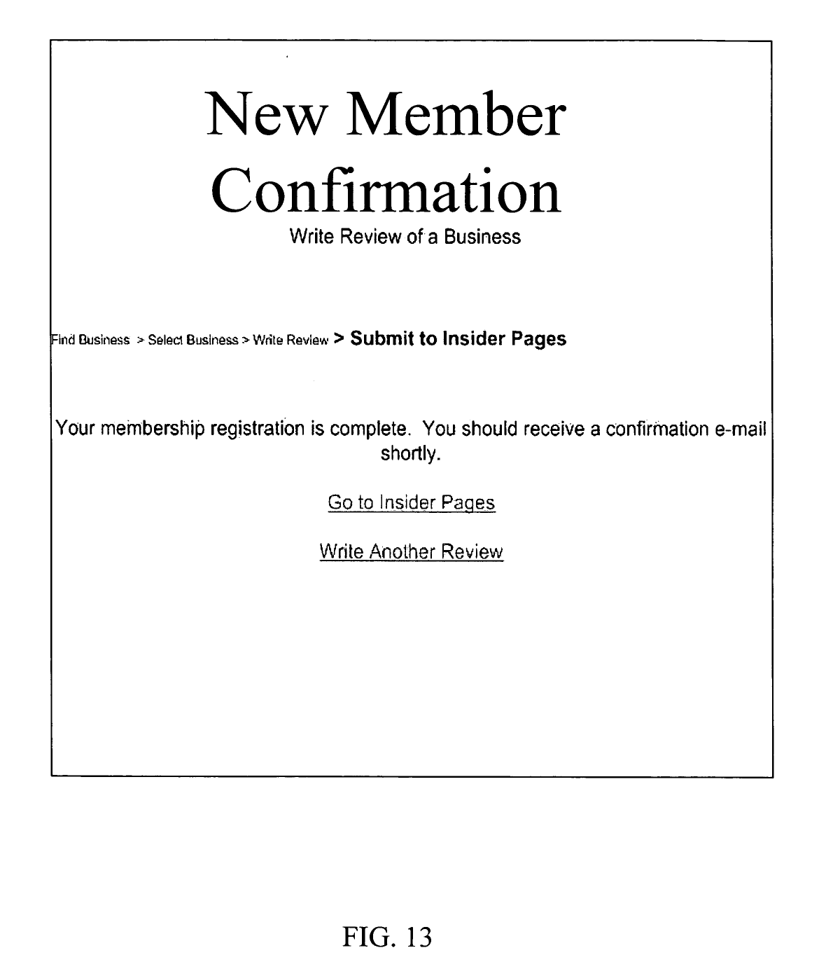

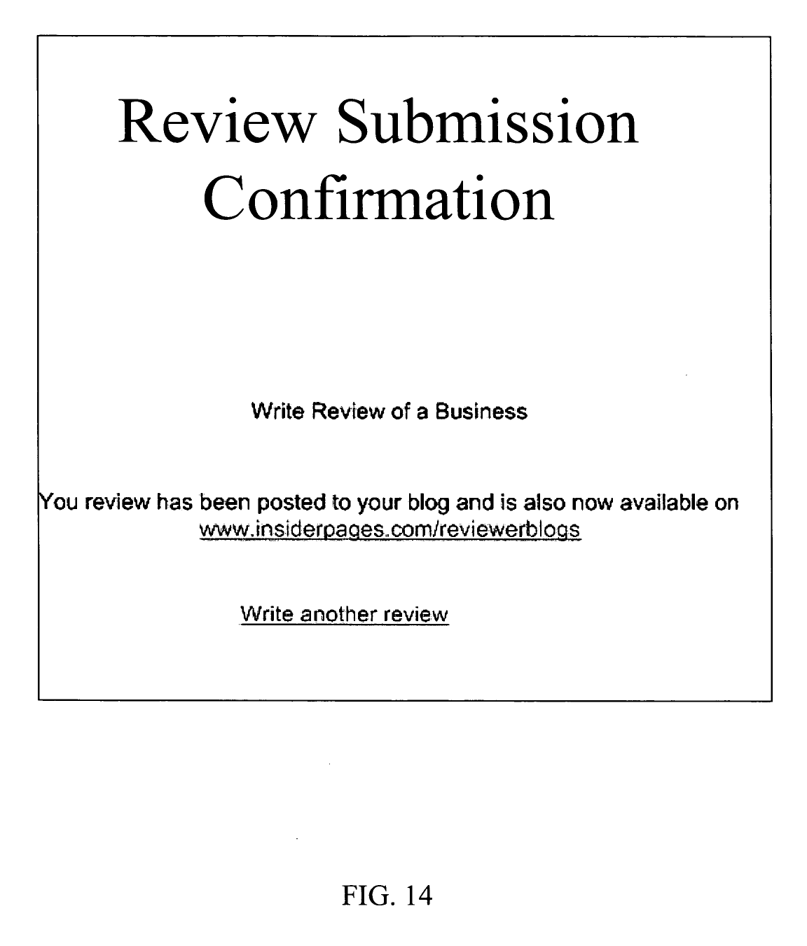

FIG. 13 is an example page informing users that their registration or membership within the PN blog manager 130 has been successfully completed, under an embodiment. FIG. 14 is an example page informing users that their blogs have been published or posted successfully, under an embodiment. A confirming email, e.g., confirming registration and publication, may also be sent to the user via email.

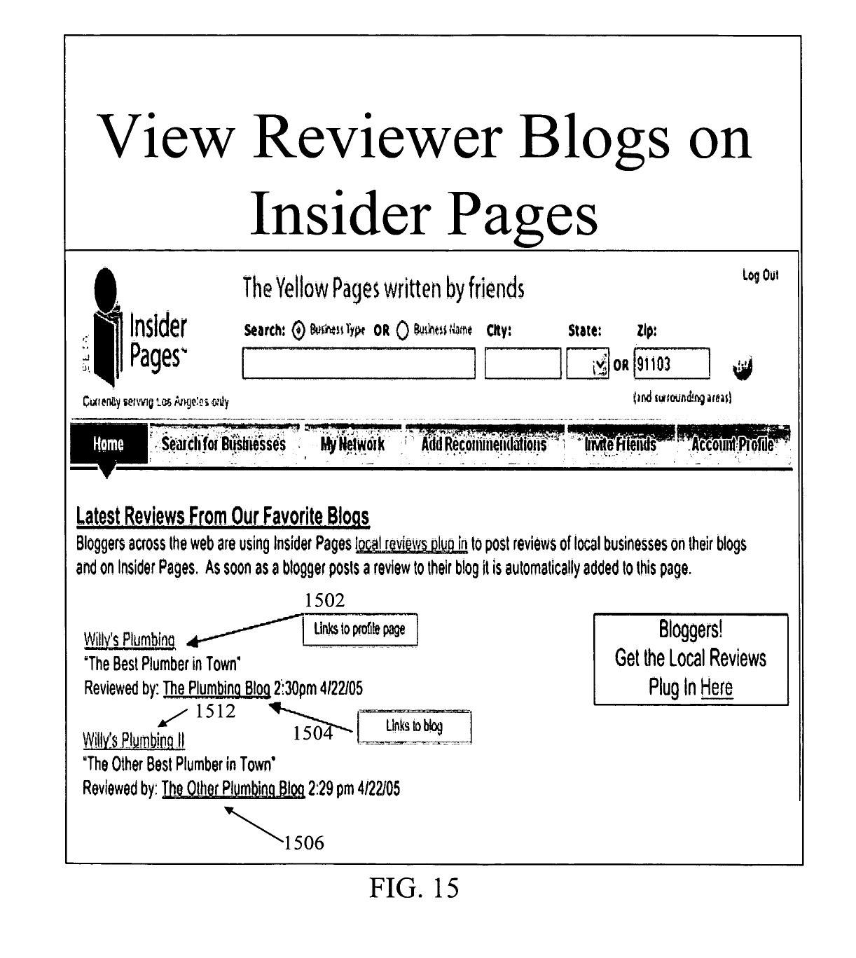

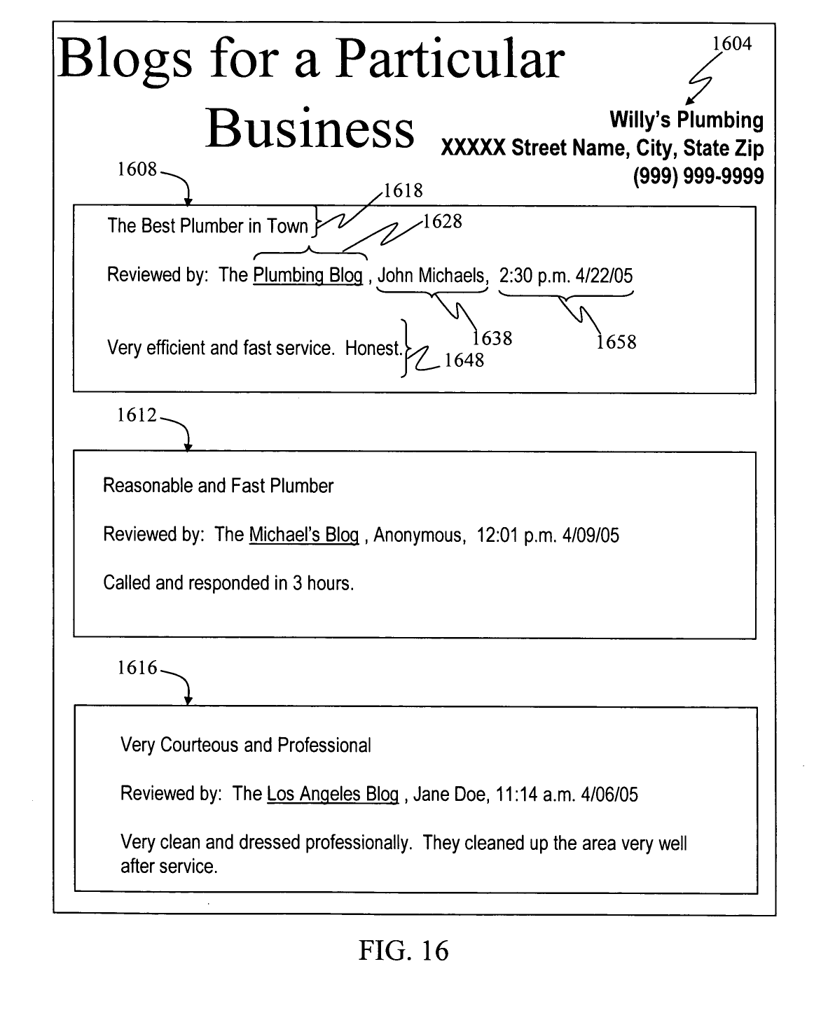

FIG. 15 is an example page, for example provided by the PN blog manager, showing blogs stored in the blogs database 432 but also submitted to third-party blog managers, in this example, “The Plumbing Blog” 1504 and “The Other Plumbing Blog” 1506, under an embodiment. These blogs were posted to these third-party blog managers using the structured blogging interface of the present invention. The business 1502, 1512 associated with each blog is also shown. This example page may also be a general blog page, wherein blogs from anonymous users are posted. In another embodiment, this page presents all blogs from all users, for example ordered in reverse chronological order, with certain older blogs deleted. Hyperlinks 1502, 1512 to associated entities/businesses are also made available. Blogs published by anonymous users are incorporated only in this type of page and not displayed in other page types, e.g., FIG. 16.

FIG. 16 is an example entity/business blog page, for example provided by the PN blog manager, showing three blogs 1608, 1612, 1616 associated with a particular entity, e.g., Willy's Plumbing 1604, under an embodiment. In this example page, each blog includes a title 1618, the third-party blog manager(s) 1628 that the blog was also accordingly transmitted, a user name 1638, a date-time stamp 1658, and the user blog entry/comment 1648. A reciprocal link 1628 to the URL of the third-party blog manager, e.g., home page or blog page of the “Plumbing Blog,” is also present. The blogs 1608, 1612, 1616 are for example presented in reverse chronological order.

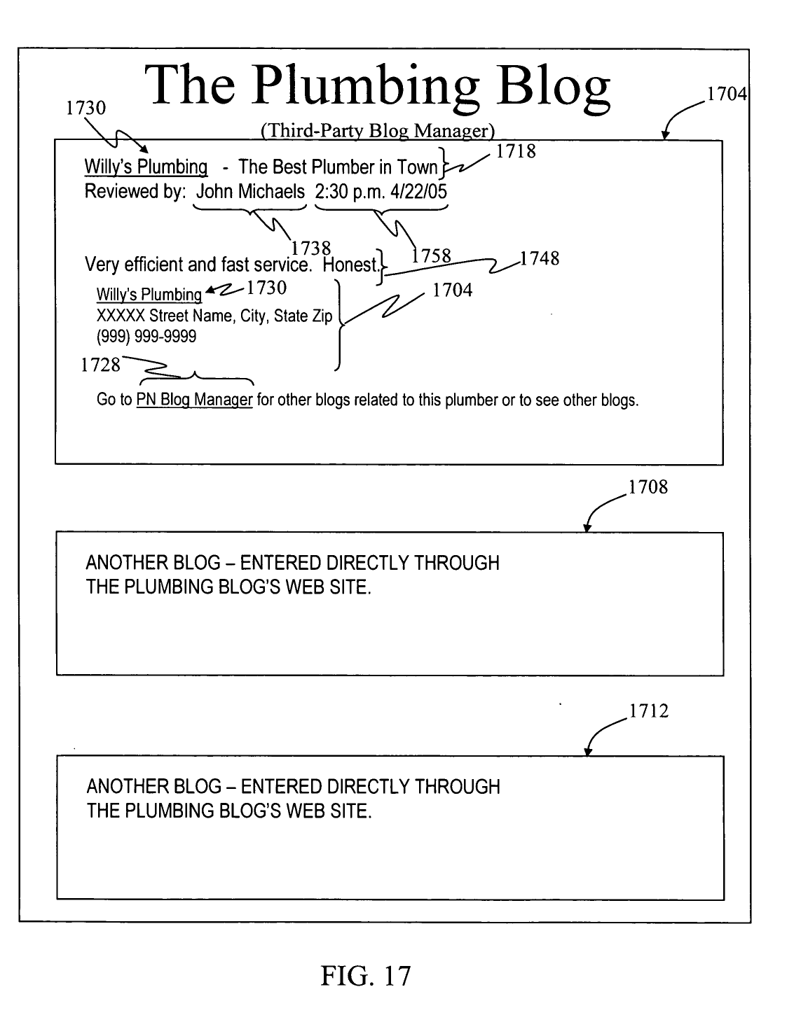

FIG. 17 is an example page of a third-party blog manager, in this example, the “Plumbing Blog,” accessible by the hyperlink 1628 in FIG. 16, under an embodiment. The hyperlink may also just be for the home page of this blog manager. This page shows entries from three blogs, the last two entries 1708, 1712 for example directly entered by other people via the third-party blog manager's website, for example, via the “Plumbing's blog” web site. The first blog entry is a structured blog entryl704 posted to this third-party blog manager via the structured blogging interface of the present invention. For example, the structured blog entry posted or transmitted includes the title 1718, the user name 1738, if available, the date-time stamp 1758, the blog entry/comment 1748, the entity/business information 1704, and a reciprocal link 1728 to the PN blog manager. Furthermore, clicking on the “Willy's Plumbing” link 1730 for example redirects the user to the entity/business page, e.g., FIG. 16, served by the PN blog manager 130.

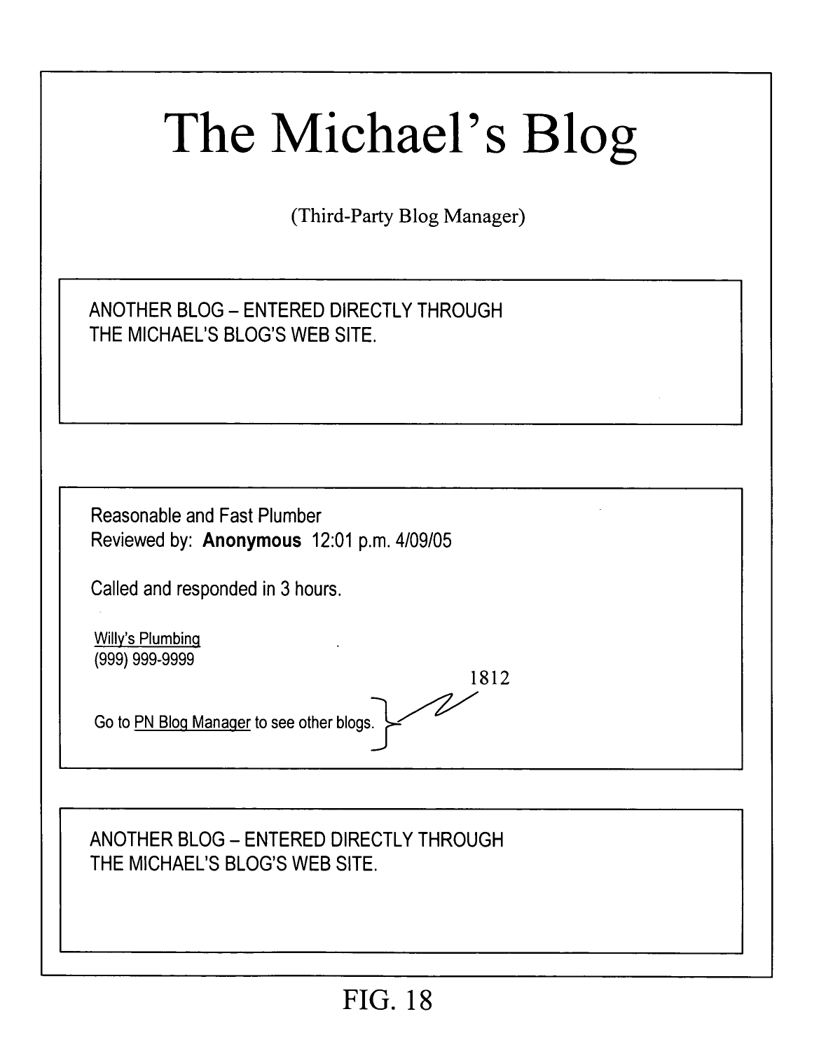

FIG. 18 is another example page of a third-party blog manager, “The Michael's Blog” (second blog 1612 in FIG. 16), under an embodiment. A reciprocal link to the PN block manager 1812 is for example sent to the third-party blog manager.

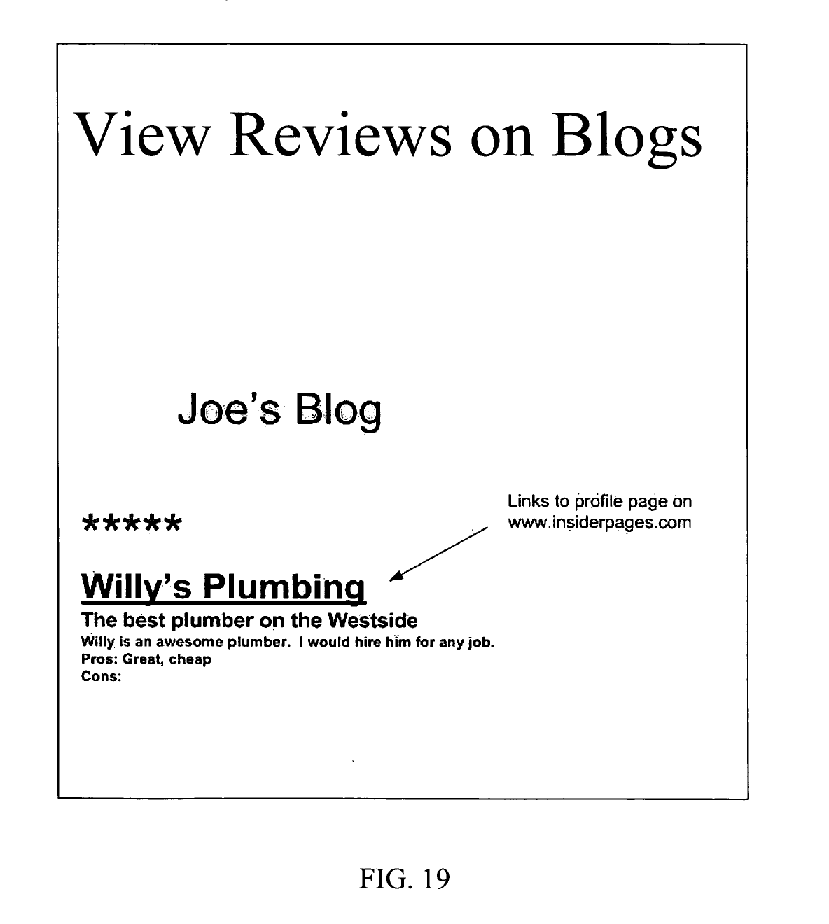

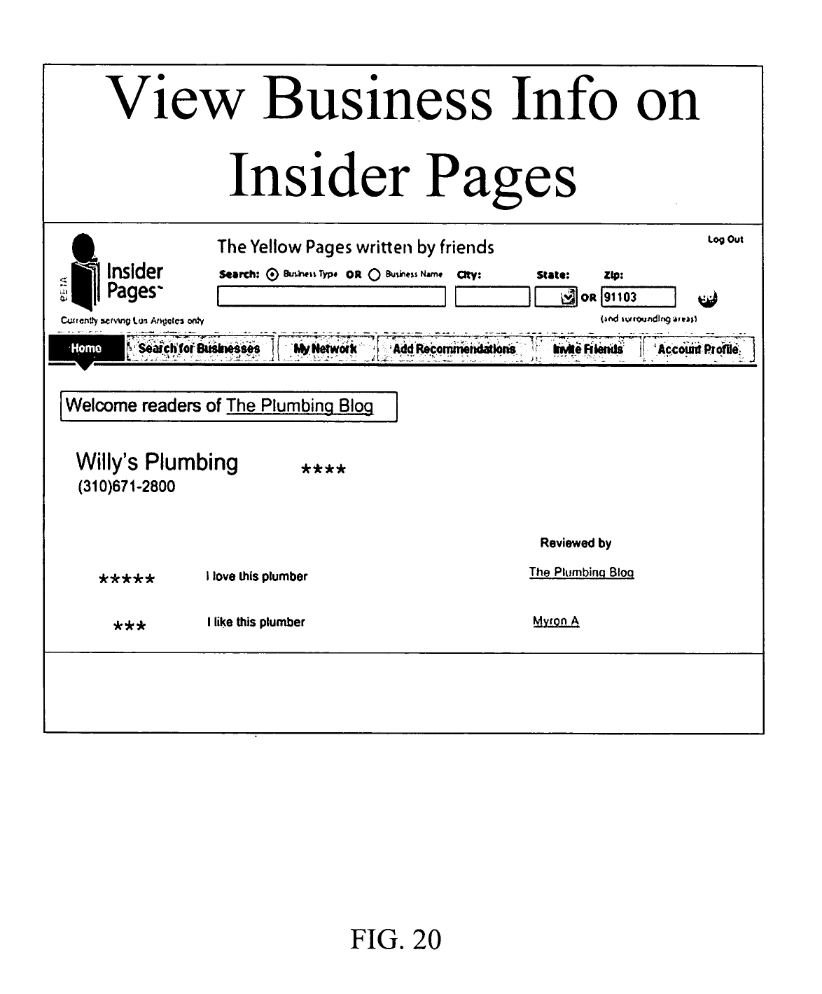

FIG. 19 is another example third-party blog manager's page showing a link to the PN blog manager, under an embodiment. This link links to FIG. 16, served by the PN blog manager.

FIG. 20 is an example page served by the PN blog manager, under an embodiment. This page is another variation of FIG. 16. For example, only blogs from registered users are posted within this entity/business blog page type.

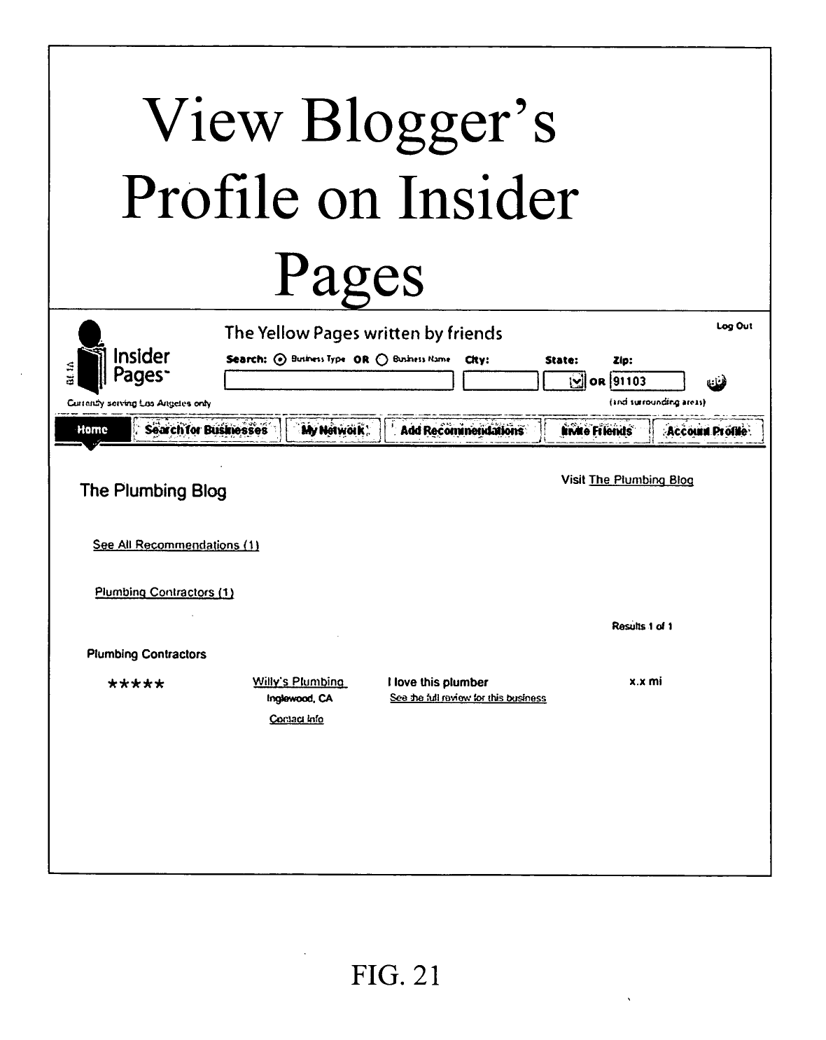

FIG. 21 is an example third-party blog manager's profile page, for example served by the PN blog manager, under an embodiment. This page shows blogs that were posted to the “Plumbing Blog” third-party blog manager's website that have a corresponding structured blog record in the PN blog manager. This page enables users to view blog entries posted to various third-party blog managers using the structured blogging interface of the present invention.

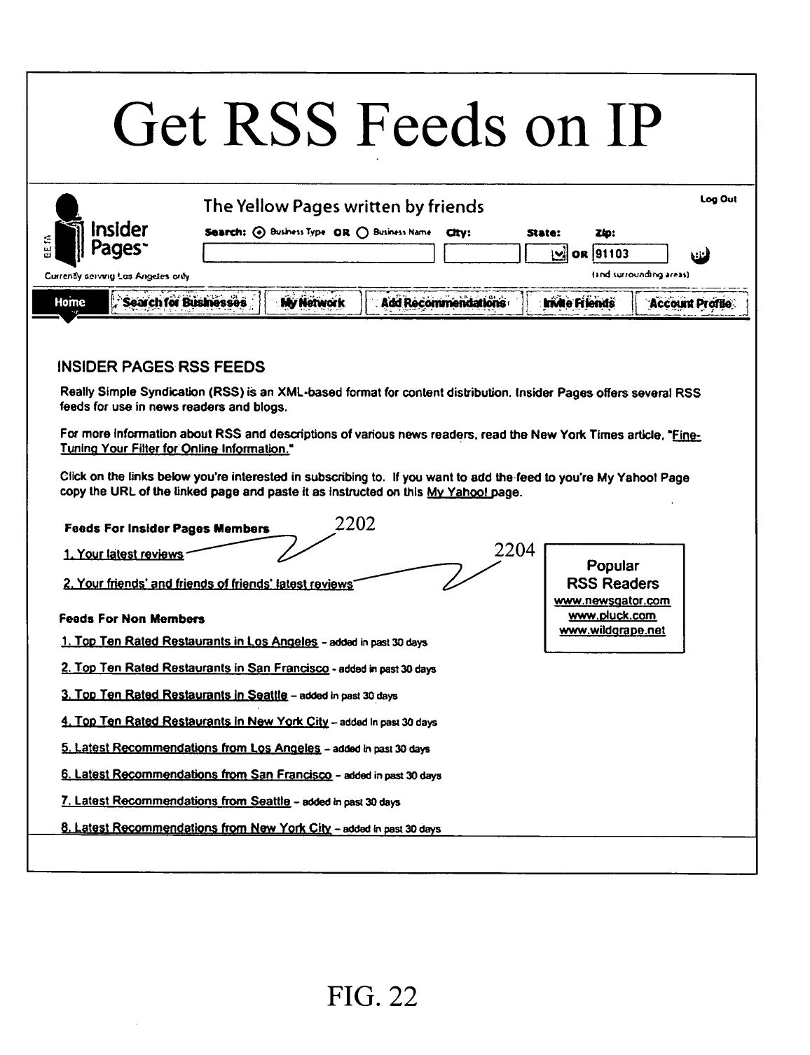

FIG. 22 is an example page enabling a user to receive RSS feeds, via a plug-in interface independent or incorporated in the structured blogging interface plug-in, under an embodiment. In this embodiment, a user is enabled to receive various data feeds, such as those in RSS format. In an embodiment, a user is able to receive feeds showing all structured blogs submitted by that user 2202. In an embodiment, a user is able to receive feeds based on certain personal contact network conditions, such as receiving blogs from friends who are one to four connections away (see FIG. 7A-7E). In another embodiment, a user may receive feeds posted about a certain entity/business, such that blogs posted via the structured blog interface or those directly to the PN blog manager, for example, related to Willy's Plumbing may be fed to the user on a regular basis.

Other example interfaces may also be presented by the PN blog manager, for example, a page showing all blog entries posted by a registered user, all blog entries related to local businesses, all blog entries related to a certain user profile conditions, all blog entries of local businesses with a four-star rating or more, all blog entries from direct friends from the past thirty days, or all blog entries posted within the last thirty days to various third-party blog managers from local users.

The Blog systems of an embodiment include a method for blogging. The method for blogging of an embodiment includes receiving an input from a user and generating a structured weblog (blog) including information of the input. The method for blogging of an embodiment includes transferring the structured blog to a plurality of blog managers. The method for blogging of an embodiment includes linking the structured blogs of each of the plurality of blog managers by generating a reciprocal link between the structured blog of each of the plurality of blog managers.

Generating the structured blog of an embodiment includes generating a structured format data set that includes the input and related information.

The method for blogging of an embodiment includes associating the input with the related information. The related information of an embodiment comprises one or more of user information, identification information, time stamp information, entity contact information, journal information, comments, and reviews.

The structured blog of an embodiment includes metadata, wherein the information of the input and the metadata are structured according to one or more structures.

Generating the structured blog of an embodiment comprises generating the structured blog to include the reciprocal link.

Generating the structured blog of an embodiment comprises generating an association between the structured blog and the reciprocal link.

The reciprocal link of an embodiment includes one or more of a hyperlink to a website, a hyperlink to one or more of the plurality of blog managers, and a hyperlink to the structured blog.

The plurality of blog managers of an embodiment includes one or more of private network blog managers and public network blog managers.

Transferring the structured blog to a plurality of blog managers of an embodiment includes transferring the structured blog to a personal blog manager and one or more third-party blog managers.

The personal blog manager of an embodiment is a component of a personal network and the third-party blog manager is a component of a third-party network defined by the user.

The method for blogging of an embodiment includes one or more of transferring data of the input to a first blog manager, generating the structured blog at the first blog manager, the structured blog including the reciprocal link, and transferring the structured blog from the first blog manager to a second blog manager of the plurality of blog managers. The first blog manager of an embodiment is a component of a personal network and the second blog manager is third-party blog manager. The first blog manager of an embodiment is a third-party blog manager and the second blog manager is a component of a personal network. The first blog manager of an embodiment is an intermediate blog manager, and the second blog manager is one or more of a component of a personal network and a third-party blog manager.

The method for blogging of an embodiment includes modifying content of the structured blog at a first blog manager. The method for blogging of an embodiment includes automatically updating a corresponding reciprocal structured blog at a second blog manager.

The method for blogging of an embodiment includes one or more of generating a request to update a corresponding reciprocal structured blog at a second blog manager; and transferring the request to update to the second blog manager.

The method for blogging of an embodiment includes generating and tracking relational information of a relationship between an associated blog. The associated blogs of an embodiment correspond to the structured blog.

The method for blogging of an embodiment includes forming at least one affinity network among a plurality of users. A type of the affinity network of an embodiment includes one or more of familial relationship, common interest, geographical location, personal knowledge profession, user similarity, age, income, demographic data, and gender.

The method for blogging of an embodiment includes enabling one or more of accessing, filtering, and searching the structured blog in response to relationship information the plurality of users of the affinity network.

The Blog systems of an embodiment include a system comprising at least one weblog (blog) system coupled to a processor. The system of an embodiment is configured to receive an input from a user and generate a structured weblog (blog) including information of the input. The system of an embodiment is configured to transfer the structured blog to a plurality of blog managers. The system of an embodiment is configured to link the structured blogs of each of the plurality of blog managers by generating a reciprocal link between the structured blog of each of the plurality of blog managers.

Configured to generate the structured blog of an embodiment includes configured to generate a structured format data set that includes the input and related information. The blog system of an embodiment is configured to associate the input with the related information. The related information of an embodiment comprises one or more of user information, identification information, time stamp information, entity contact information, journal information, comments, and reviews.

The structured blog of an embodiment further includes metadata. The information of the input and the metadata of an embodiment are structured according to one or more structures.

Configured to generate the structured blog of an embodiment comprises configured to one or more of generate the structured blog to include the reciprocal link and generate an association between the structured blog and the reciprocal link.

The reciprocal link of an embodiment includes one or more of a hyperlink to a website, a hyperlink to one or more of the plurality of blog managers, and a hyperlink to the structured blog.

The plurality of blog managers of an embodiment includes one or more of private network blog managers and public network blog managers.

The blog system of an embodiment is configured to one or more of transfer data of the input to a first blog manager, generate the structured blog at the first blog manager, the structured blog including the reciprocal link, and transfer the structured blog from the first blog manager to a second blog manager of the plurality of blog managers.

The blog system of an embodiment is configured to one or more of modify content of the structured blog at a first blog manager, and update a corresponding reciprocal structured blog at a second blog manager.

The blog system of an embodiment is configured to generate and track relational information of a relationship between an associated blog, wherein the associated blogs correspond to the structured blog.

The blog system of an embodiment is configured to form at least one affinity network among a plurality of users. A type of the affinity network of an embodiment includes one or more of familial relationship, common interest, geographical location, personal knowledge profession, user similarity, age, income, demographic data, and gender. The blog system of an embodiment is configured to enable one or more of accessing, filtering, and searching the structured blog in response to relationship information the plurality of users of the affinity network.

The plurality of blog managers of an embodiment includes one or more servers.

The Blog systems of an embodiment include a method of structured blogging. The method of structured blogging of an embodiment includes receiving a blog record comprising a user-provided blog entry. The method of structured blogging of an embodiment includes formatting the blog record into a structured blog format. The structured blog format includes entity information associated with the user-provided blog entry and at least one link to a blog manager. The method of structured blogging of an embodiment includes sending the structured blog format to one or more third-party blog managers.

The Blog systems of an embodiment include a computer readable medium including executable instructions which, when executed in a processing system, manage blogging. The blogging of an embodiment includes receiving an input from a user and generating a structured weblog (blog) including information of the input. The blogging of an embodiment includes transferring the structured blog to a plurality of blog managers. The blogging of an embodiment includes linking the structured blogs of each of the plurality of blog managers by generating a reciprocal link between the structured blog of each of the plurality of blog managers.

Although this invention has been disclosed in the context of certain embodiments and examples, it will be understood by those skilled in the art that the present invention extends beyond the specifically disclosed embodiments to other alternative embodiments and/or uses of the invention and obvious modifications and equivalents thereof. In addition, while a number of variations of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. Accordingly, it should be understood that various features and aspects of the disclosed embodiments can be combined with or substituted for one another in order to form varying modes of the disclosed invention. Thus, it is intended that the scope of the present invention herein disclosed should not be limited by the particular disclosed embodiments described above.

Unless otherwise indicated, the functions described herein are performed by programs or sets of program codes, including software, firmware, executable code or instructions running on or otherwise being executed by one or more general-purpose computers or processor-based systems. The computers or other processor-based systems may include one or more central processing units for executing program code, volatile memory, such as RAM for temporarily storing data and data structures during program execution, non-volatile memory, such as a hard disc drive or optical drive, for storing programs and data, including databases and other data stores, and a network interface for accessing an intranet and/or the Internet. However, the present invention may also be implemented using special purpose computers, wireless computers, state machines, and/or hardwired electronic circuits.

Throughout the following description, the term “Web site” is used to refer to a user-accessible network site that implements the basic World Wide Web standards for the coding and transmission of documents. These network sites may also be accessible by program modules executed in computing devices, such as computers, interactive television, interactive game devices, wireless web-enabled devices, and the like. The standards typically include a language such as the Hypertext Markup Language (HTML) and a transfer protocol such as the Hypertext Transfer Protocol (HTTP). Other protocols may also be used such as file transfer protocol (FTP), wireless application protocol (WAP) and other languages such as the extensible markup language (XML) and wireless markup language (WML). It should be understood that the term “site” is not intended to imply a single geographic location, as a Web or other network site can, for example, include multiple geographically-distributed computer systems that are appropriately linked and/or clustered together. Furthermore, while the following description explains by example an embodiment utilizing the Internet and related protocols, other networks, whether wired or wireless, and other protocols may be used as well.

The databases or other data stores described herein can be combined into fewer databases, or partitioned or divided into additional databases. In addition, the example processes described herein do not necessarily have to be performed in the described sequence, and not all states have to be reached or performed. Various database management systems or data formats may also be used, such as object-oriented database management systems, relational database management systems, flat files, text files, linked lists, arrays, and stacks. Furthermore, flags, Boolean fields, pointers, and other software engineering techniques or algorithmic procedures may be incorporated in the data management system to implement the features of the present invention.

Embodiments of the present invention may reside in the client side, in the server side, or in both places. Such embodiments, for example, program modules may be created using various tools as known in the art. For example, client side programming or manipulation may include programs written in various programming languages or applications, such as C++, Visual Basic, Basic, C, assembly language, FLASH™ from Macromedia, and machine language. Program modules interfacing with web browsers, such as plug-ins and MICROSOFT™ active X controls, Java Scripts, and applets may also be implemented. Server side modules may also be written in programming languages previously mentioned and including other server programming languages, such as Perl, Java, Hypertext Preprocessor (PHP), ColdFusion of Macromedia, etc. Databases shown residing, for example, on the server side may also reside or only reside on the client side. Similarly, databases discussed that may reside on the client side may also reside or only reside in the server side. Client and server refer to the client-server architecture.

What is claimed is:

1. A method for blogging, comprising:
receiving an input from a user and generating a structured weblog (blog) including information of the input;
transferring the structured blog to a plurality of blog managers; and
linking the structured blogs of each of the plurality of blog managers by generating a reciprocal link between the structured blog of each of the plurality of blog managers.

2. The method of claim 1, wherein generating the structured blog includes generating a structured format data set that includes the input and related information.

3. The method of claim 1, further comprising associating the input with the related information, wherein the related information comprises one or more of user information, identification information, time stamp information, entity contact information, journal information, comments, and reviews.

4. The method of claim 1, wherein the structured blog further includes metadata, wherein the information of the input and the metadata are structured according to one or more structures.

5. The method of claim 1, wherein generating the structured blog comprises generating the structured blog to include the reciprocal link.

6. The method of claim 1, wherein generating the structured blog comprises generating an association between the structured blog and the reciprocal link.

7. The method of claim 1, wherein the reciprocal link includes one or more of a hyperlink to a website, a hyperlink to one or more of the plurality of blog managers, and a hyperlink to the structured blog.

8. The method of claim 1, wherein the plurality of blog managers include one or more of private network blog managers and public network blog managers.

9. The method of claim 1, wherein transferring the structured blog to a plurality of blog managers includes transferring the structured blog to a personal blog manager and one or more third-party blog managers.

10. The method of claim 9, wherein the personal blog manager is a component of a personal network and the third-party blog manager is a component of a third-party network defined by the user.

11. The method of claim 1, further comprising:
transferring data of the input to a first blog manager;
generating the structured blog at the first blog manager, the structured blog including the reciprocal link; and
transferring the structured blog from the first blog manager to a second blog manager of the plurality of blog managers.

12. The method of claim 11, wherein the first blog manager is a component of a personal network and the second blog manager is third-party blog manager.

13. The method of claim 11, wherein the first blog manager is a third-party blog manager and the second blog manager is a component of a personal network.

14. The method of claim 11, wherein the first blog manager is an intermediate blog manager, and the second blog manager is one or more of a component of a personal network and a third-party blog manager.

15. The method of claim 1, further comprising modifying content of the structured blog at a first blog manager.

16. The method of claim 15, further comprising automatically updating a corresponding reciprocal structured blog at a second blog manager.

17. The method of claim 15, further comprising:
generating a request to update a corresponding reciprocal structured blog at a second blog manager; and;
transferring the request to update to the second blog manager.

18. The method of claim 1, further comprising generating and tracking relational information of a relationship between an associated blog, wherein the associated blogs correspond to the structured blog.

19. The method of claim 1, further comprising forming at least one affinity network among a plurality of users, wherein a type of the affinity network includes one or more of familial relationship, common interest, geographical location, personal knowledge profession, user similarity, age, income, demographic data, and gender.

20. The method of claim 19, further comprising enabling one or more of accessing, filtering, and searching the structured blog in response to relationship information the plurality of users of the affinity network.

21. A system comprising at least one weblog (blog) system coupled to a processor, the blog system configured to:
receive an input from a user and generate a structured weblog (blog) including information of the input;
transfer the structured blog to a plurality of blog managers; and
link the structured blogs of each of the plurality of blog managers by generating a reciprocal link between the structured blog of each of the plurality of blog managers.

22. The system of claim 21, wherein configured to generate the structured blog includes configured to generate a structured format data set that includes the input and related information, wherein the blog system is further configured to associate the input with the related information, wherein the related information comprises one or more of user information, identification information, time stamp information, entity contact information, journal information, comments, and reviews.

23. The system of claim 21, wherein the structured blog further includes metadata, wherein the information of the input and the metadata are structured according to one or more structures.

24. The system of claim 21, wherein configured to generate the structured blog comprises configured to one or more of generate the structured blog to include the reciprocal link and generate an association between the structured blog and the reciprocal link.

25. The system of claim 21, wherein the reciprocal link includes one or more of a hyperlink to a website, a hyperlink to one or more of the plurality of blog managers, and a hyperlink to the structured blog.

26. The system of claim 21, wherein the plurality of blog managers include one or more of private network blog managers and public network blog managers.

27. The system of claim 21, wherein the blog system is configured to:
transfer data of the input to a first blog manager;
generate the structured blog at the first blog manager, the structured blog including the reciprocal link; and
transfer the structured blog from the first blog manager to a second blog manager of the plurality of blog managers.

28. The system of claim 21, wherein the blog system is configured to:
modify content of the structured blog at a first blog manager;
update a corresponding reciprocal structured blog at a second blog manager.

29. The system of claim 21, wherein the blog system is configured to generate and track relational information of a relationship between an associated blog, wherein the associated blogs correspond to the structured blog.

30. The system of claim 21, wherein the blog system is configured to form at least one affinity network among a plurality of users, wherein a type of the affinity network includes one or more of familial relationship, common interest, geographical location, personal knowledge profession, user similarity, age, income, demographic data, and gender, wherein the blog system is configured to enable one or more of accessing, filtering, and searching the structured blog in response to relationship information the plurality of users of the affinity network.

31. The system of claim 21, wherein the plurality of blog managers include one or more servers.

32. A method of structured blogging, comprising:
receiving a blog record comprising a user-provided blog entry;
formatting the blog record into a structured blog format, wherein the structured blog format includes entity information associated with the user-provided blog entry and at least one link to a blog manager; and
sending the structured blog format to one or more third-party blog managers.

33. Computer readable medium including executable instructions which, when executed in a processing system, manage blogging, by:
receiving an input from a user and generating a structured weblog (blog) including information of the input;
transferring the structured blog to a plurality of blog managers; and
linking the structured blogs of each of the plurality of blog managers by generating a reciprocal link between the structured blog of each of the plurality of blog managers.
